(19) United States
(12) Patent Application Publication
(10) Pub. No.: US 2024/0363652 A1
(43) Pub. Date: Oct. 31, 2024

(54) DEEP TRENCH CAPACITOR STRUCTURE AND METHODS OF FORMATION

(71) Applicant: Taiwan Semiconductor Manufacturing Company, Ltd., Hsinchu (TW)

(72) Inventors: Chao-Hsuan CHANG, Taipei City (TW); Hsiu-Yun LIEN, Tainan City (TW); Ming HUNG, Taipei City (TW); Tung-I LIN, Tainan City (TW); Chun CHANG, Tainan City (TW); Chao-Ching CHANG, Kaohsiung City (TW); Sheng-Chan LI, Tainan City (TW); Sheng-Chau CHEN, Tainan City (TW)

(21) Appl. No.: 18/308,928

(22) Filed: Apr. 28, 2023

(51) Int. Cl. H01L 27/146

(52) U.S. Cl. CPC H01L 27/14609; H01L 27/14603; H01L 27/14632; H01L 27/14636; H01L 28/75; H01L 28/91; H01L 28/92

(57) ABSTRACT

A deep trench capacitor structure may include a metal-insulator-metal structure having an insulator layer between opposing conductive electrode layers. The deep trench capacitor structure may extend through a plurality of dielectric layers in a semiconductor device. The conductive electrode layers and the insulator layer may extend laterally into the dielectric layers. The lateral extensions of the conductive electrode layers and the insulator layer into the dielectric layers may be referred to as fin portions of the capacitor structure. The fin portions may extend laterally outward from a central portion (e.g., a trench portion) of the deep trench capacitor structure. The fin portions of the deep trench capacitor structure enable the surface area of the conductive electrode layers to be increased, which may increase the capacitance of the deep trench capacitor structure with minimal increase to the overall footprint of the deep trench capacitor structure.

### BACKGROUND

A complementary metal oxide semiconductor (CMOS) image sensor may include a plurality of pixel sensors. A pixel sensor of the CMOS image sensor may include a transfer transistor, which may include a photodiode configured to convert photons of incident light into a photocurrent of electrons and a transfer gate configured to control the flow of the photocurrent between the photodiode and a drain region. The drain region may be configured to receive the photocurrent such that the photocurrent can be measured and/or transferred to other areas of the CMOS image sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of a portion of an example semiconductor device described herein.

FIGS. 3A-3D are diagrams of example implementations of a deep trench capacitor structure having a plurality of fin portions described herein.

FIGS. 4A-4J are diagrams of an example implementation of forming a deep trench capacitor structure having a plurality of fin portions described herein.

FIG. 5 is a diagram of an example implementation of a trench and lateral extension regions in which a deep trench capacitor structure having a plurality of fin portions described herein may be formed.

FIG. 6 is a diagram of an example implementation of a trench and lateral extension regions in which a deep trench capacitor structure having a plurality of fin portions described herein may be formed.

FIG. 7 is a diagram of an example implementation of a deep trench capacitor structure having a plurality of fin portions described herein.

FIG. 8 is a diagram of an example implementation of a deep trench capacitor structure having a plurality of fin portions described herein.

FIG. 9 is a diagram of an example implementation of etch rates for forming lateral extension regions described herein.

FIG. 10 is a diagram of an example semiconductor device described herein.

FIG. 11 is a diagram of an example semiconductor device described herein.

FIG. 12 is a diagram of an example semiconductor device described herein.

FIG. 13 is a diagram of example components of a device described herein.

FIG. 14 is a flowchart of an example process associated with forming a deep trench capacitor structure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An image sensor device (e.g., a complementary metal oxide semiconductor (CMOS) image sensor (CIS) device) may include one or more capacitor structures in a back end of line (BEOL) region of the image sensor device. A capacitor structure may perform and/or support one or more functions in the image sensor device, such as analog to digital (A/D) conversion, increasing capacitance per unit area for pixel sensors of the image sensor device, and/or another function.

In some implementations, a capacitor structure in an image sensor device may be configured to support the operation of a shutter associated with the image sensor device. A shutter is a component that enables selective exposure of pixel sensors in a pixel sensor array of the image sensor device to light. Shutters are often included in digital cameras to enable the capture of discrete images or photographs. The capacitor structure may enable the use of a “global shutter” technique or a “total shutter” technique, where the entire pixel sensor array is exposed simultaneously. At the start of a global shutter exposure operation, each pixel sensor in the pixel sensor array may begin to accumulate a charge due to exposure to light. The charge may be stored in the capacitor structure and transferred to a readout circuit at the end of the global shutter exposure operation.

A capacitor structure, such as a deep trench capacitor (DTC) structure in an image sensor device, may include a metal-insulator-metal (MIM) structure in which an insulator layer is sandwiched between two conductive electrode layers. The capacitance of the capacitor structure (e.g., the amount of charge that can be stored by the capacitor structure) is directly dependent on the geometry of the conductive electrode layers of the capacitor structure. The greater the area of the conductive electrode layers, the greater the capacitance of the capacitor structure. Thus, increasing the size of the metal electrode layers may increase the capacitance of the capacitor structure.

However, increasing the size of the capacitor structure is in direct contention with semiconductor design principles in the semiconductor industry, in which reducing semiconductor device sizes is pursued to achieve reduced power consumption, to achieve greater operating performance and efficiencies, and/or to enable semiconductor devices to be used in increasingly smaller form factor applications. Reducing the size of a semiconductor device, such as an image sensor device, may result in a need to proportionately reduce the size of a capacitor structure in the semiconductor device, which may result in reduced capacitance and/or reduced performance for the capacitor structure. Moreover, reducing the size of the semiconductor device may increase the difficulty of manufacturing the capacitor structure in that smaller dimensions for the capacitor structure may result in reduced manufacturing tolerances for the capacitor structure, which may result in an increased defect rate in capacitor structures of the semiconductor device. An increased defect rate in capacitor structures of the semiconductor device may result in reduced performance for the semiconductor device and/or may result in an increased rate of scraping semiconductor devices that include capacitor structures, among other examples.

In some implementations described herein, a semiconductor device, such as an image sensor device, may include a deep trench capacitor structure in a BEOL region of the semiconductor device. The capacitor structure may include a MIM structure having an insulator layer between opposing conductive electrode layers. The deep trench capacitor structure may extend through a plurality of dielectric layers in the BEOL region. The conductive electrode layers and the insulator layer may extend laterally into one or more of the dielectric layers. The lateral extensions of the conductive electrode layers and the insulator layer into the one or more dielectric layers may be referred to as fin portions of the capacitor structure. The fin portions may extend laterally outward from a central portion (e.g., a trench portion) of the deep trench capacitor structure.

The fin portions of the deep trench capacitor structure enable the surface area of the conductive electrode layers to be increased (e.g., relative to the conductive electrode layers extending vertically through the dielectric layers and etch stop layers), which may increase the capacitance of the deep trench capacitor structure with minimal increase to the overall footprint of the deep trench capacitor structure. In this way, the fin portions enable the size of the semiconductor device to be decreased, and/or the density of components in the semiconductor device to be increased, while achieving the same or greater capacitance for the deep trench capacitor structures included in the semiconductor device.

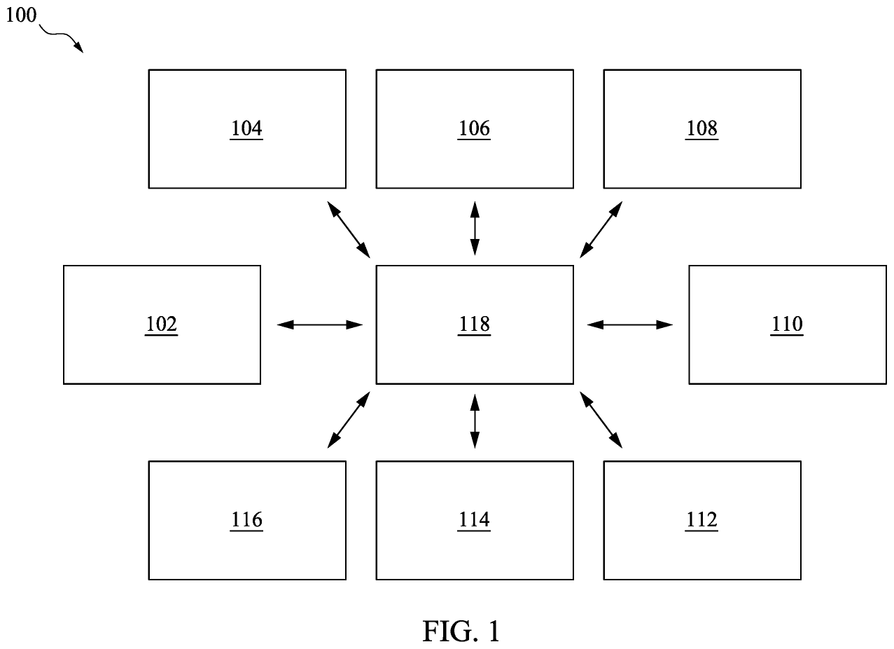

FIG. 1 is a diagram of an example environment 100 in which systems and/or methods described herein may be implemented. As shown in FIG. 1, environment 100 may include a plurality of semiconductor processing tools 102-116 and a wafer/die transport tool 118. The plurality of semiconductor processing tools 102-116 may include a deposition tool 102, an exposure tool 104, a developer tool 106, an etch tool 108, a planarization tool 110, a plating tool 112, an ion implantation tool 114, a bonding tool 116, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

The bonding tool 116 is a semiconductor processing tool that is capable of bonding two or more wafers (or two or more semiconductor substrates, or two or more semiconductor devices) together. For example, the bonding tool 116 may include a eutectic bonding tool that is capable of forming a eutectic bond between two or more wafers together. In these examples, the bonding tool may heat the two or more wafers to form a eutectic system between the materials of the two or more wafers. As another example, the bonding tool 116 may include a hybrid bonding tool, a direct bonding tool, and/or another type of bonding tool.

The wafer/die transport tool 118 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 118 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

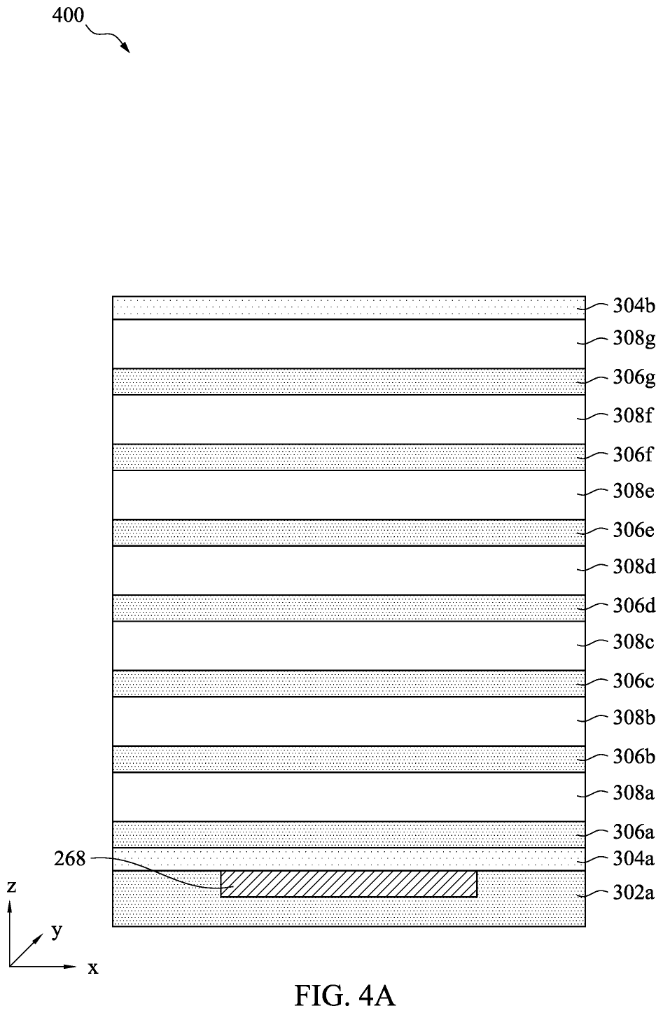

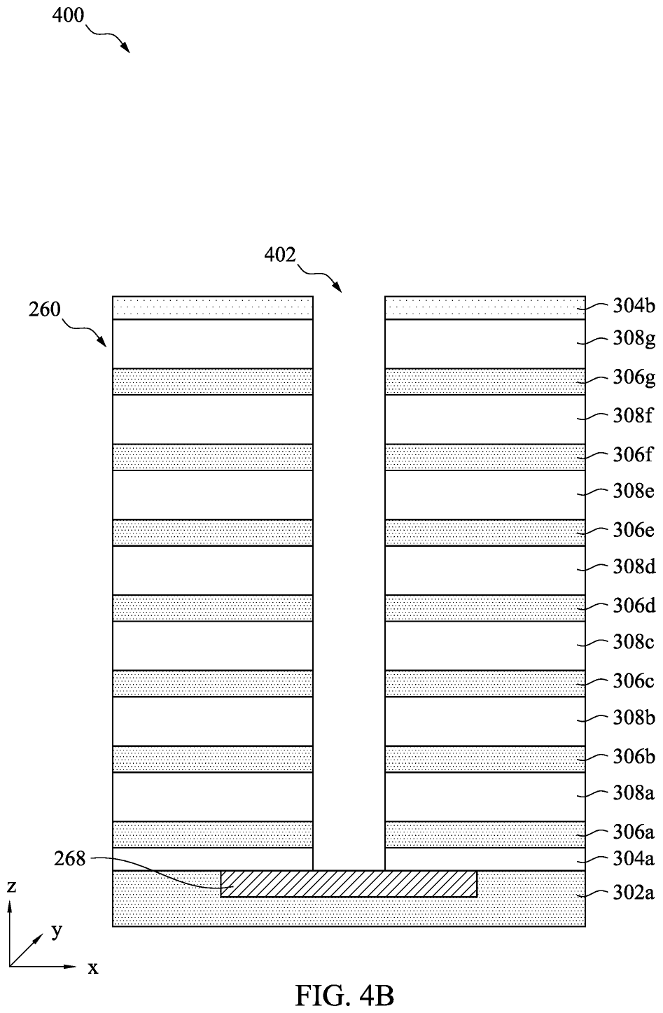

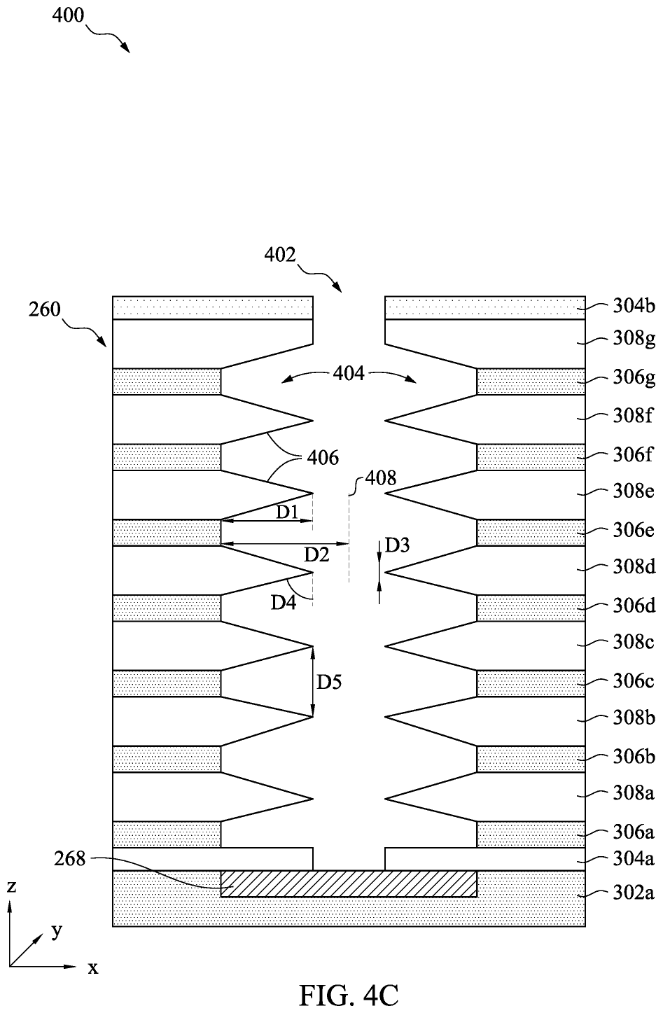

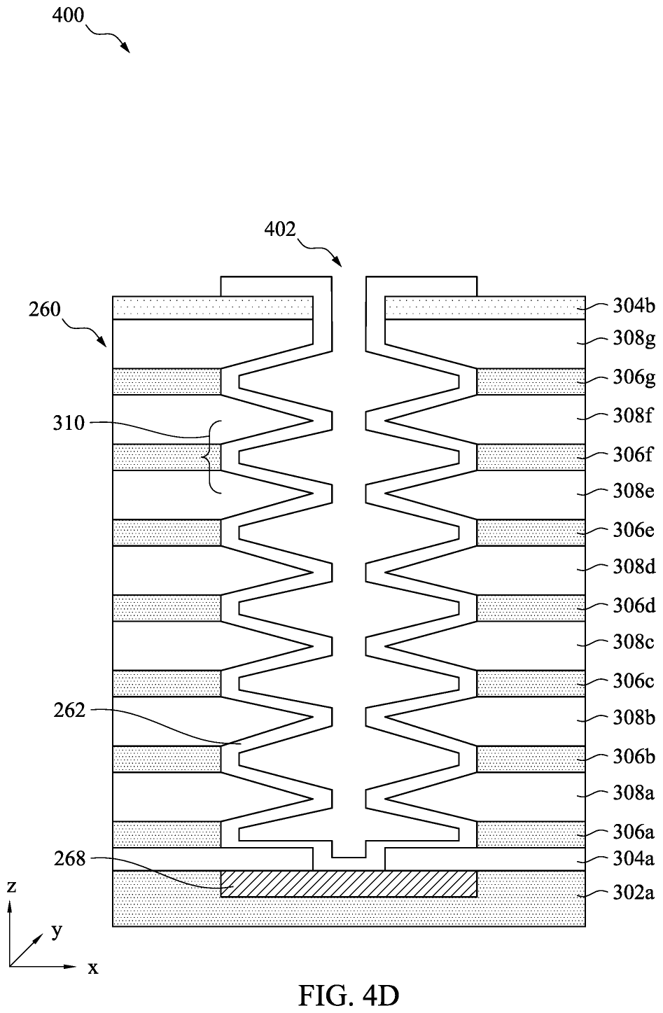

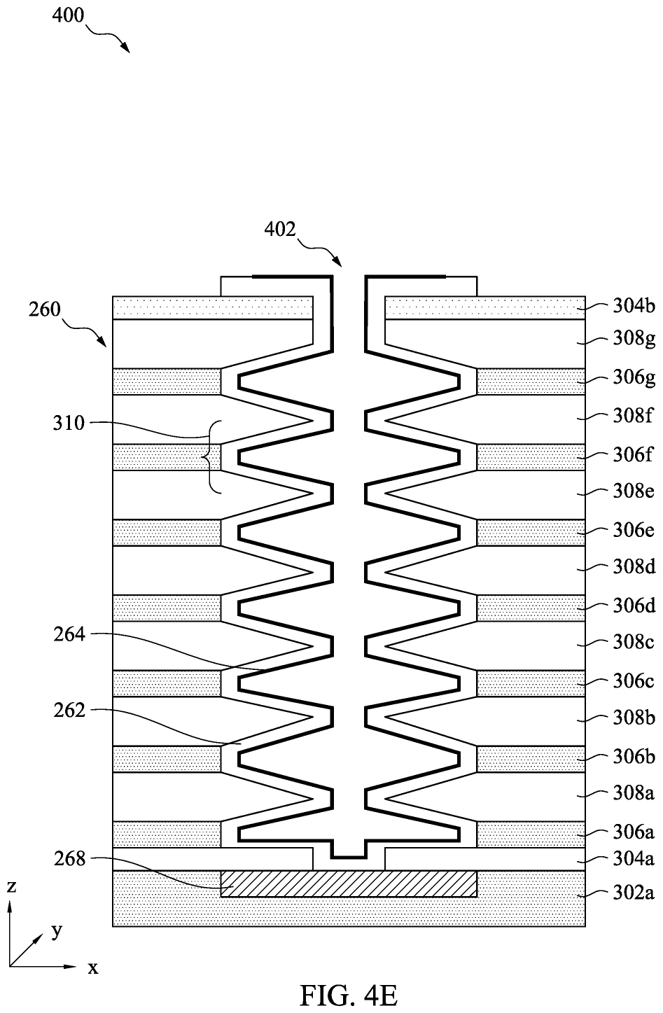

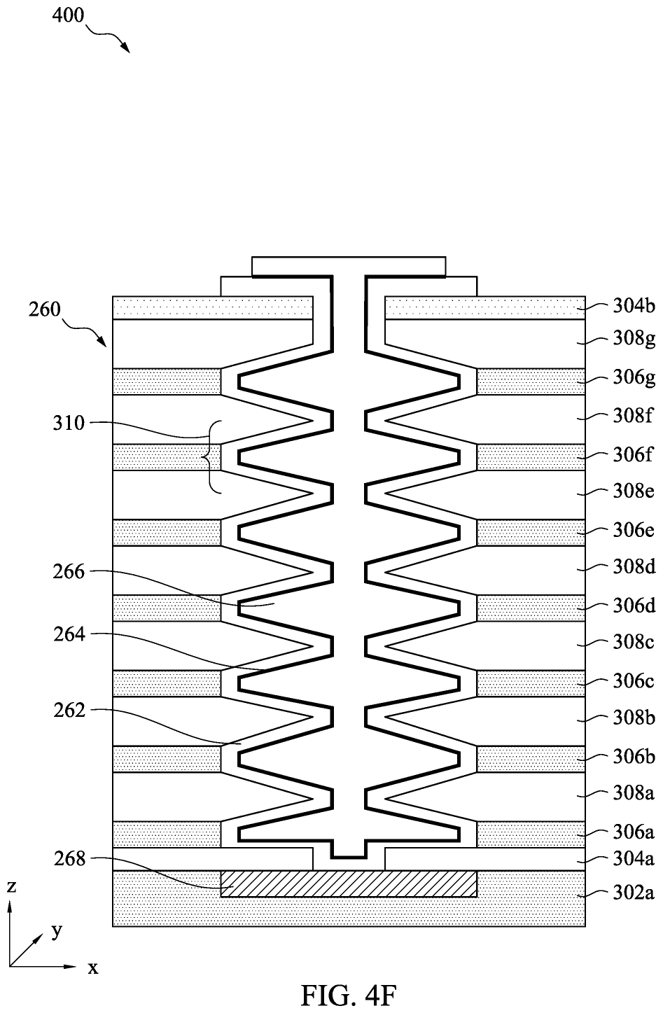

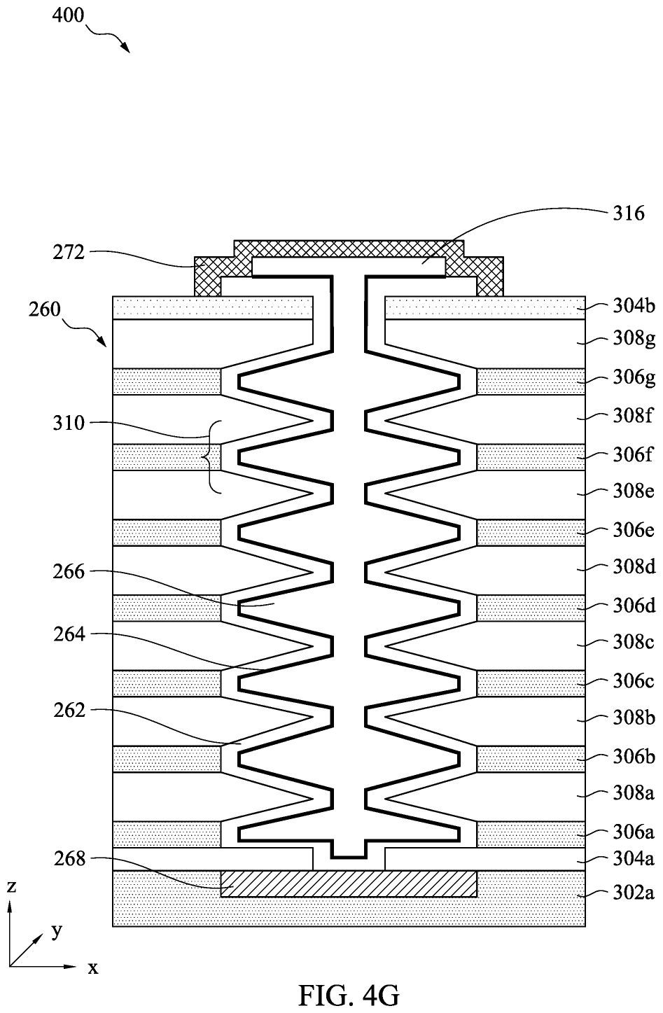

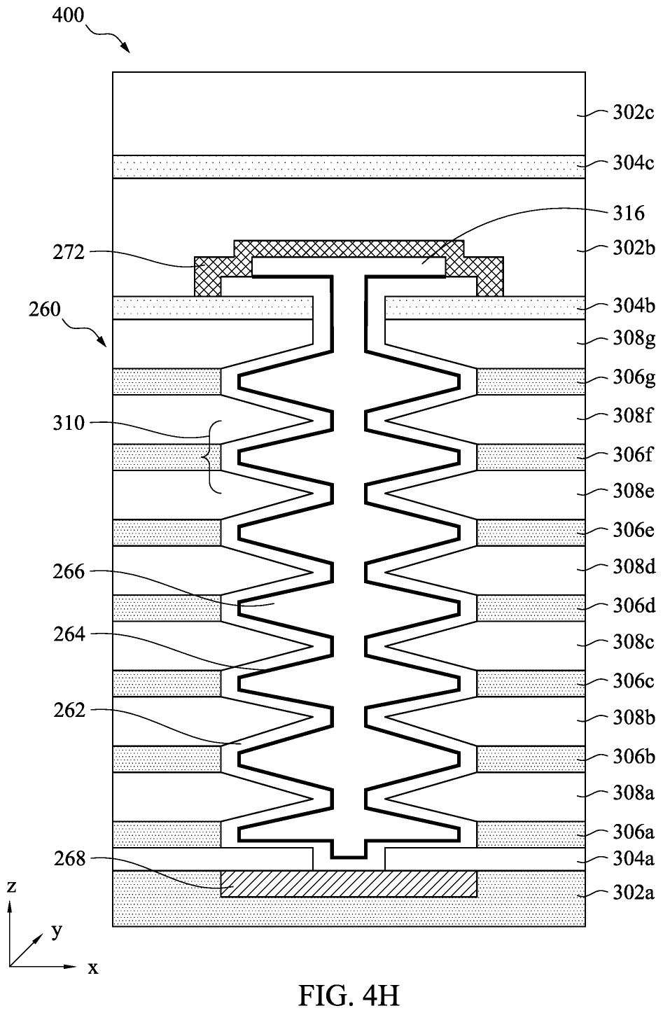

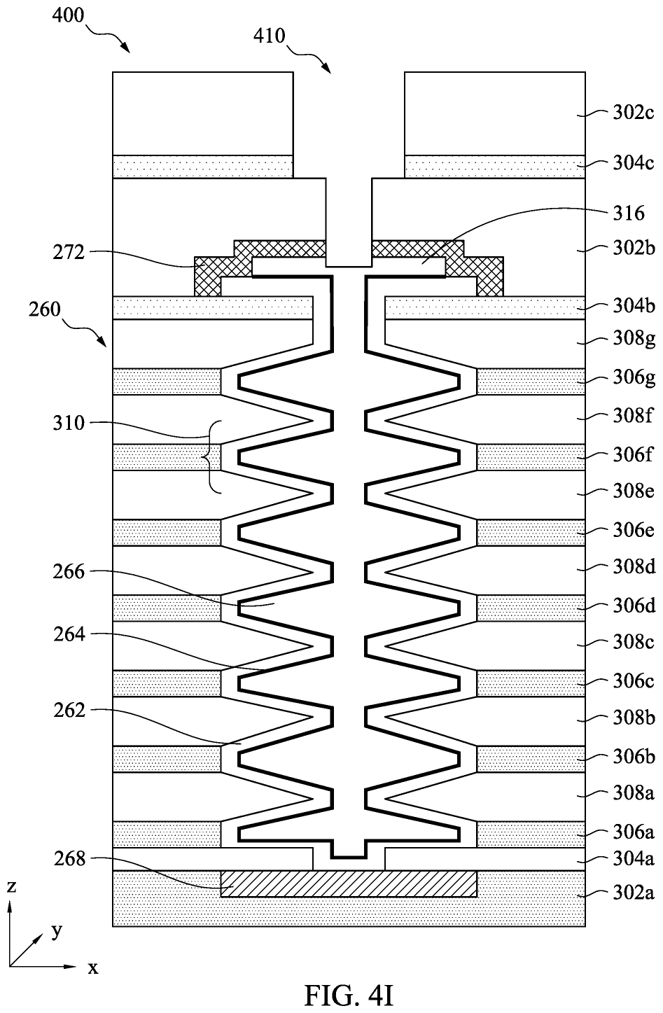

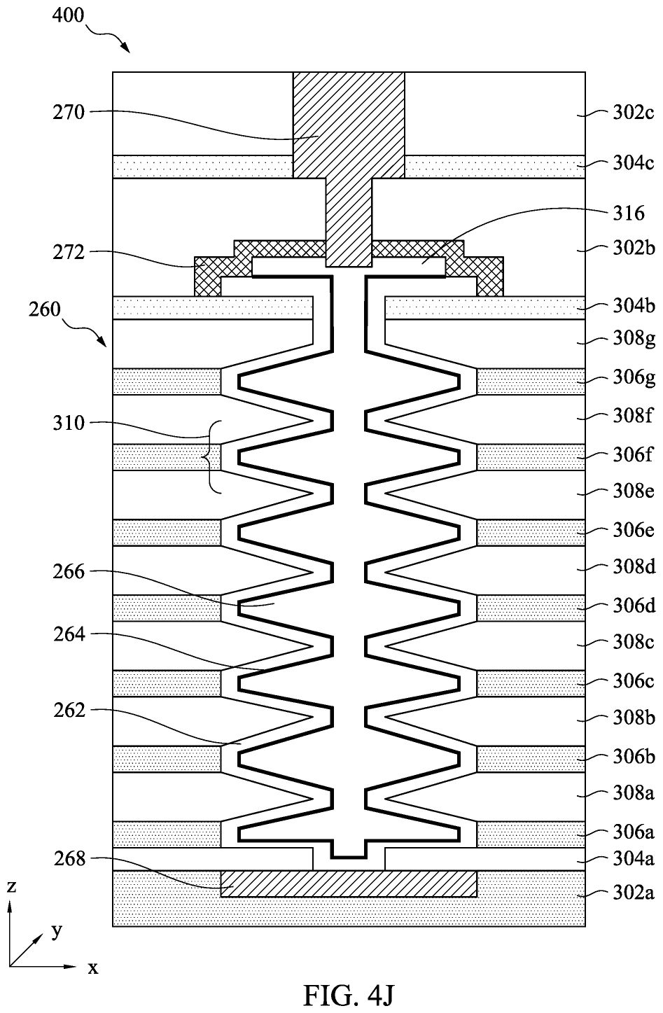

In some implementations, one or more of the semiconductor processing tools 102-116 and/or the wafer/die transport tool 118 may perform one or more semiconductor processing operations described herein. For example, one or more of the semiconductor processing tools 102-116 and/or the wafer/die transport tool 118 may form a trench through a first plurality of dielectric layers and a second plurality of dielectric layers, where the first plurality of dielectric layers and the second plurality of dielectric layers are arranged in an alternating configuration in a first direction in a semiconductor device; may form a plurality of lateral extension regions that laterally extend from the trench and into the first plurality of dielectric layers; may form, along sidewalls of the plurality of lateral extension regions, a first conductive layer of a deep trench capacitor structure; may form an insulator layer of the deep trench capacitor structure on the first conductive layer; and/or may for a second conductive layer of the deep trench capacitor structure on the insulator layer, among other examples. In some implementations, one or more of the semiconductor processing tools 102-116 and/or the wafer/die transport tool 118 may perform one or more semiconductor processing operations described herein, such as one or more semiconductor processing operations described in connection with FIGS. 4A-4J and/or 12, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100

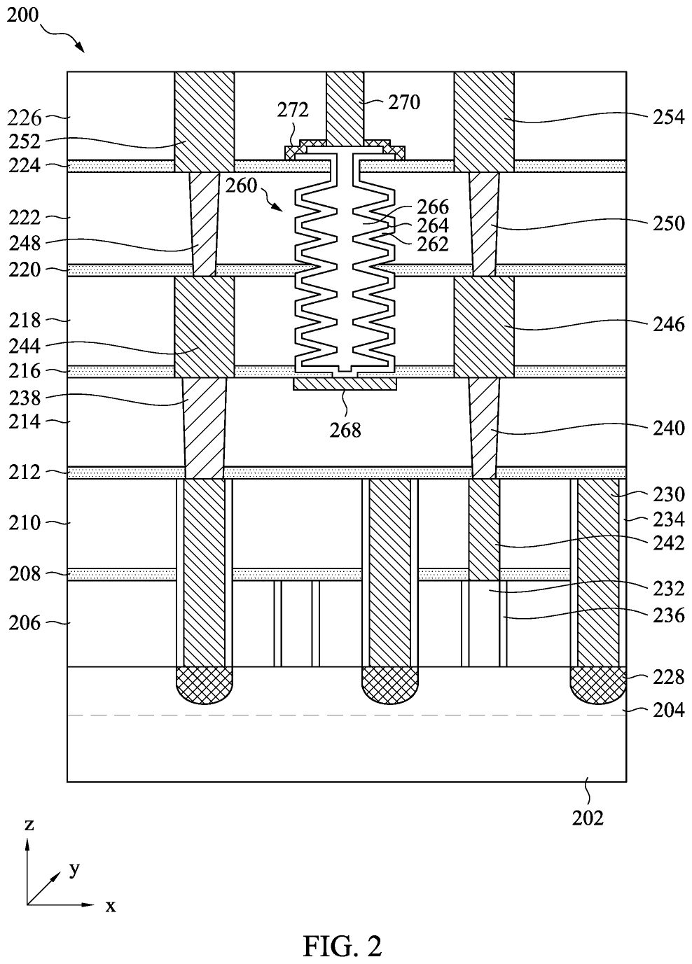

FIG. 2 is a diagram of a portion of an example semiconductor device 200 described herein. The semiconductor device 200 includes an example of a semiconductor device, such as a semiconductor memory device (e.g., a static random access memory (SRAM), a dynamic random access memory (DRAM)), an image sensor device (e.g., a complementary metal oxide semiconductor (CMOS) image sensor (CIS) device), a semiconductor logic device, a processor, an input/output device, or another type of semiconductor device that includes one or more transistors.

The semiconductor device 200 includes a substrate 202 and one or more stacked layers, including a dielectric layer 206, an etch stop layer (ESL) 208, a dielectric layer 210, an ESL 212, a dielectric layer 214, an ESL 216, a dielectric layer 218, an ESL 220, a dielectric layer 222, an ESL 224, and a dielectric layer 226, among other examples. The dielectric layers 206, 210, 214, 218, 222, and 226 are included to electrically isolate various structures of the semiconductor device 200. The dielectric layers 206, 210, 214, 218, 222, and 226 include a silicon nitride (SiNₓ), an oxide (e.g., a silicon oxide (SiOₓ) and/or another oxide material), and/or another type of dielectric material. The ESLs 208, 212, 216, 220, 224 includes a layer of material that is configured to permit various portions of the semiconductor device 200 (or the layers included therein) to be selectively etched or protected from etching to form one or more of the structures included in the semiconductor device 200.

As further shown in FIG. 2, the semiconductor device 200 includes a plurality of epitaxial (epi) regions 228 that are grown and/or otherwise formed on and/or around portions of the fin structure 204. The epitaxial regions 228 are formed by epitaxial growth. In some implementations, the epitaxial regions 228 are formed in recessed portions in the fin structure 204. The recessed portions may be formed by strained source drain (SSD) etching of the fin structure 204 and/or another type etching operation. The epitaxial regions 228 function as source or drain regions of the transistors included in the semiconductor device 200.

The epitaxial regions 228 are electrically connected to metal source or drain contacts 230 of the transistors included in the semiconductor device 200. The metal source or drain contacts (MDs or CAs) 230 include cobalt (Co), ruthenium (Ru), and/or another conductive or metal material. The transistors further include gates 232 (MGs), which are formed of a polysilicon material, a metal (e.g., tungsten (W) or another metal), and/or another type of conductive material. The metal source or drain contacts 230 and the gates 232 are electrically isolated by one or more sidewall spacers, including spacers 234 in each side of the metal source or drain contacts 230 and spacers 236 on each side of the gate 232. The spacers 234 and 236 include a silicon oxide (SiOₓ), a silicon nitride (SiₓN_{y}), a silicon oxy carbide (SiOC), a silicon oxycarbonitride (SiOCN), and/or another suitable material. In some implementations, the spacers 234 are omitted from the sidewalls of the source or drain contacts 230.

As further shown in FIG. 2, the metal source or drain contacts 230 and the gates 232 are electrically connected to one or more types of interconnects. The interconnects electrically connect the transistors of the semiconductor device 200 and/or electrically connect the transistors to other areas and/or components of the semiconductor device 200. In some implementations, the interconnects electrically connect the transistors to a back end of line (BEOL) region of the semiconductor device 200.

The metal source or drain contacts 230 are electrically connected to source or drain interconnects 238 (e.g., source/drain vias or VDs). One or more of the gates 232 are electrically connected to gate interconnects 240 (e.g., gate vias or VGs). The interconnects 238 and 240 include a conductive material such as tungsten, cobalt, ruthenium, copper, and/or another type of conductive material. In some implementations, the gates 232 are electrically connected to the gate interconnects 240 by gate contacts 242 (CB or MP) to reduce contact resistance between the gates 232 and the gate interconnects 240. The gate contacts 242 include tungsten (W), cobalt (Co), ruthenium (Ru), titanium (Ti), aluminum (Al), copper (Cu) or gold (Au), among other examples of conductive materials.

As further shown in FIG. 2, the interconnects 238 and 240 are electrically connected to a plurality of BEOL layers, each including one or more metallization layers and/or vias. As an example, the interconnects 238 and 240 may be electrically connected to an M0 metallization layer that includes conductive structures 244 and 246. The M0 metallization layer is electrically connected to a V0 via layer that includes vias 248 and 250. The V0 via layer is electrically connected to an M1 metallization layer that includes conductive structures 252 and 254. In some implementations, the BEOL layers of the semiconductor device 200 includes additional metallization layers and/or vias that connect the semiconductor device 200 to a package. The BEOL region of the semiconductor device 200 may refer to the region of the semiconductor device 200 above the ESL 208, including the structures/layers 210-226 and 238-254.

As further shown in FIG. 2, the semiconductor device 200 may include one or more devices and/or structures in the BEOL region of the semiconductor device 200. For example, the semiconductor device 200 may include one or more deep trench capacitor structures 260 in the BEOL region of the semiconductor device 200. The deep trench capacitor structure(s) 260 may be included in one or more of the dielectric layers 210, 214, 218, 222, and/or 226 in the BEOL region of the semiconductor device 200.

A deep trench capacitor structure 260 may include a first conductive layer 262, an insulator layer 264, and a second conductive layer 266. The first conductive layer 262 and the second conductive layer 266 may correspond to the conductive electrode layers of the deep trench capacitor structure 260. The first conductive layer 262 may be referred to as the capacitor bottom metal (CBM) layer deep trench capacitor structure 260, and the second conductive layer 266 may be referred to as the capacitor top metal (CTM) layer of the deep trench capacitor structure 260. The insulator layer 264 may be located between the first conductive layer 262 and the second conductive layer 266. The first conductive layer 262, the insulator layer 264, and the second conductive layer 266 may form a metal-insulator-metal (MIM) structure of the deep trench capacitor structure 260.

The first conductive layer 262 and the second conductive layer 266 may each include one or more electrically conductive materials, such as one or more metals, one or more metal alloys, and/or one or more of another type of electrically conductive materials. Examples include tungsten (W), cobalt (Co), ruthenium (Ru), titanium (Ti), aluminum (Al), copper (Cu) or gold (Au), titanium nitride (TiN), and/or tantalum nitride (TaN), among other examples. The insulator layer 264 may include one or more electrically insulating and/or dielectric materials. In some implementations, the insulator layer 264 includes one or more dielectric materials having a relatively high dielectric constant (high-k), such as a dielectric constant greater relative to the dielectric constant of silicon dioxide (SiO₂). Examples include zirconium oxide (ZrOₓ such as ZrO₂), aluminum oxide (AlₓO_{y} such as Al₂O₃), silicon nitride (SiₓN_{y} such as Si₃N₄), yttrium oxide (YₓO_{y} such as Y₂O₃), lanthanum oxide (LaₓO_{y} such as La₂O₃), yttrium titanium oxide (YₓTiO_{y} such as Y₂TiO₅), hafnium oxide (HfOₓ such as HfO₂), and/or tantalum oxide (TaₓO_{y} such as Ta₂O₅), among other examples.

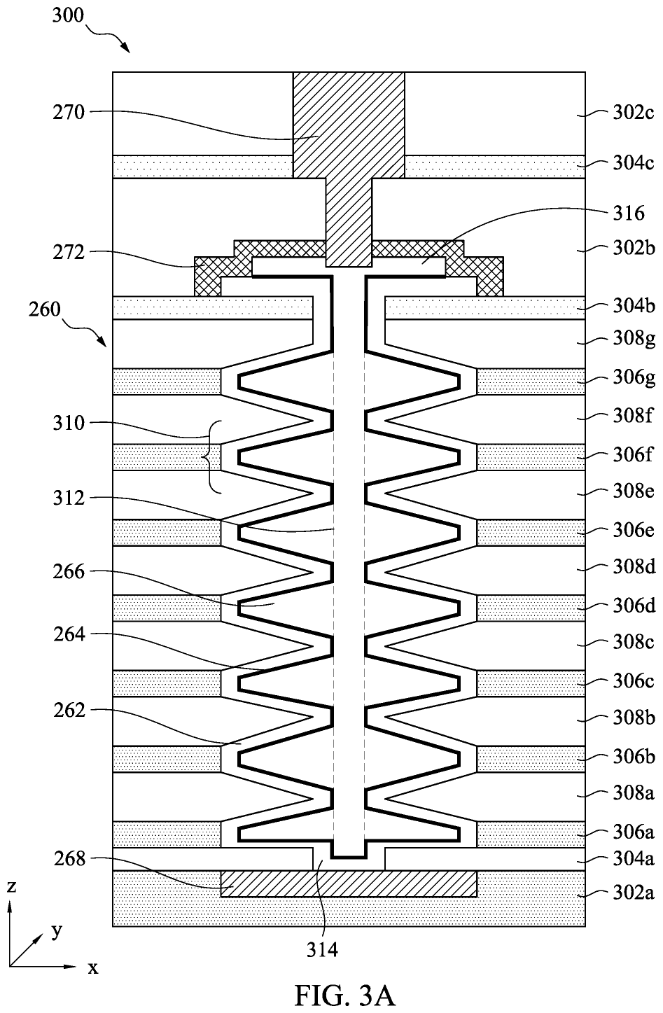

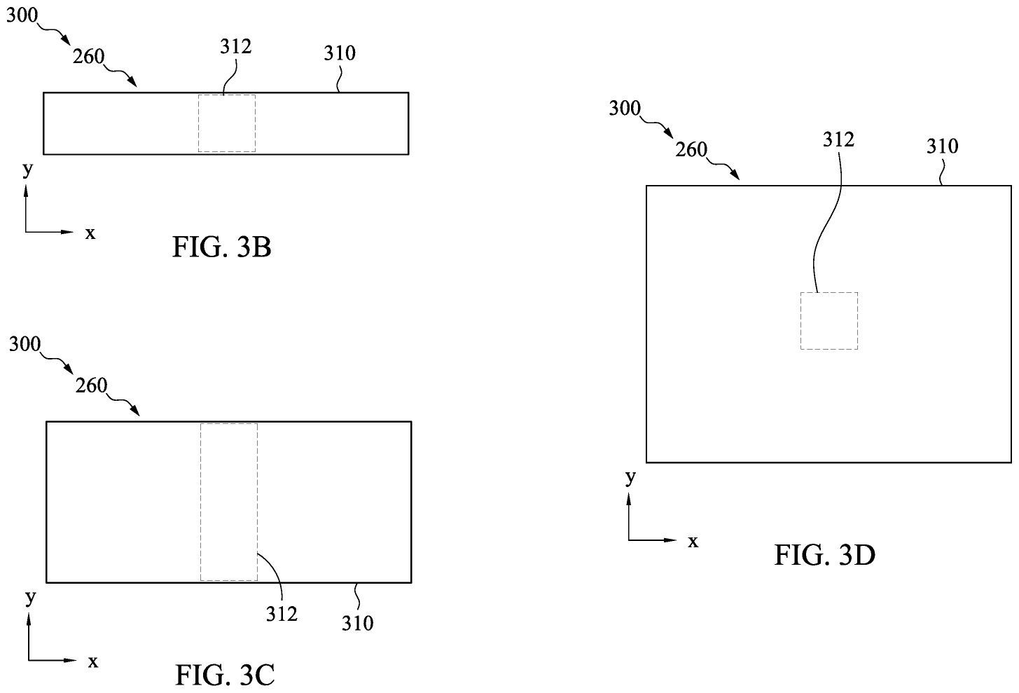

As described elsewhere herein, such as in connection with FIGS. 3A-3D, 4A-4J, 5, 6, 7, and/or 8, the deep trench capacitor structure 260 may be a fin-based deep trench capacitor structure that includes a central portion (e.g., a trench portion) and a plurality of fin portions that extend laterally outward from the central portion. The central portion may extend in the z-direction indicated in FIG. 2, and the fin portions may extend laterally outward from the central portion in the x-direction and/or in the y-direction, where the z-direction is approximately perpendicular with the x-direction and the y-direction. The fin portions may enable the area (e.g., the surface area) of the first conductive layer 262 and the second conductive layer 266 to be increased with minimal to no increase in the z-direction dimension (e.g., the depth) of the deep trench capacitor structure 260. This enables the capacitance of the deep trench capacitor structure 260 to be increased with minimal increase to the footprint of the deep trench capacitor structure 260.

As further shown in FIG. 2, the deep trench capacitor structure 260 may be electrically connected with contacts that electrically connect the deep trench capacitor structure 260 to other conductive structures in the semiconductor device 200. A bottom metal contact 268 may be located below and/or under the deep trench capacitor structure 260, and a top metal contact 270 may be located above and/or over the deep trench capacitor structure 260. The bottom metal contact 268 may be electrically connected with the first conductive layer 262 at the bottom of the deep trench capacitor structure 260. The top metal contact 270 may be electrically connected with the second conductive layer 266 at the top of the deep trench capacitor structure 260. Alternatively, the deep trench capacitor structure 260 may be electrically connected with two top metal contacts 270, and the bottom metal contact 268 may be omitted. In these implementations, the first conductive layer 262 may extend laterally outward further than the second conductive layer 266 at the top of the deep trench capacitor structure 260 to enable a second top metal contact 270 to be landed on the first conductive layer 262 without touching or contacting the first top metal contact 270 and/or the second conductive layer 266. The bottom metal contact 268 and the top metal contact 270 may each include tungsten (W), cobalt (Co), ruthenium (Ru), titanium (Ti), aluminum (Al), copper (Cu), and/or gold (Au), among other examples of conductive materials.

As further shown in FIG. 2, a capping layer 272 may be included over the top of the deep trench capacitor structure 260. The capping layer 272 may electrically isolate the deep trench capacitor structure 260 from other structures in the dielectric layer 226. Additionally and/or alternatively, the capping layer 272 may function as a hard mask layer and/or an etch stop layer during manufacturing of the deep trench capacitor structure 260.

As indicated above, FIG. 2 is provided as an example. Other examples may differ from what is described with regard to FIG. 2.

FIGS. 3A-3D are diagrams of example implementations 300 of a deep trench capacitor structure 260 having a plurality of fin portions described herein.

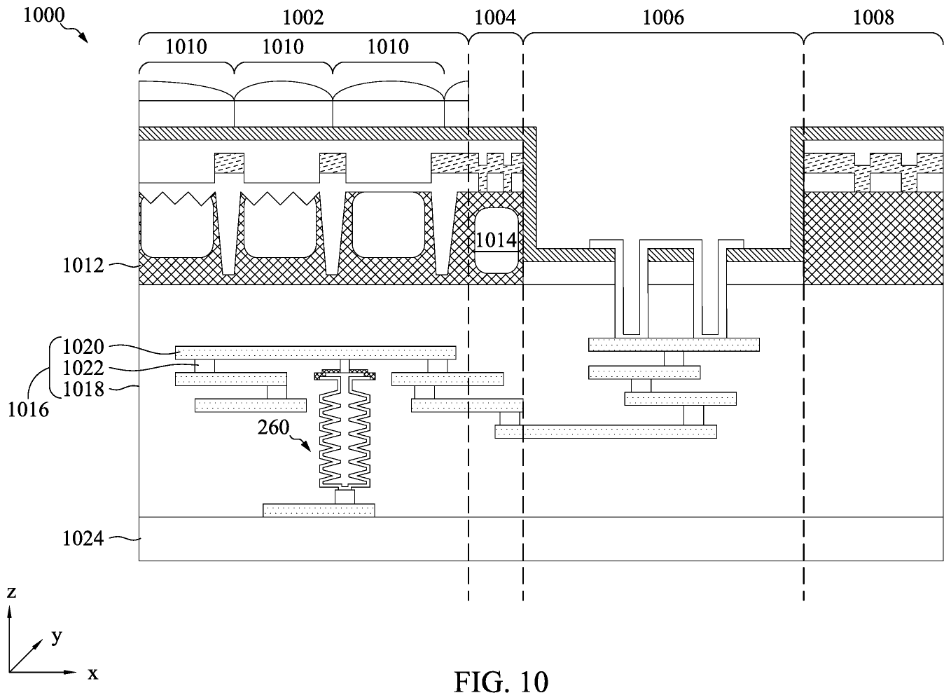

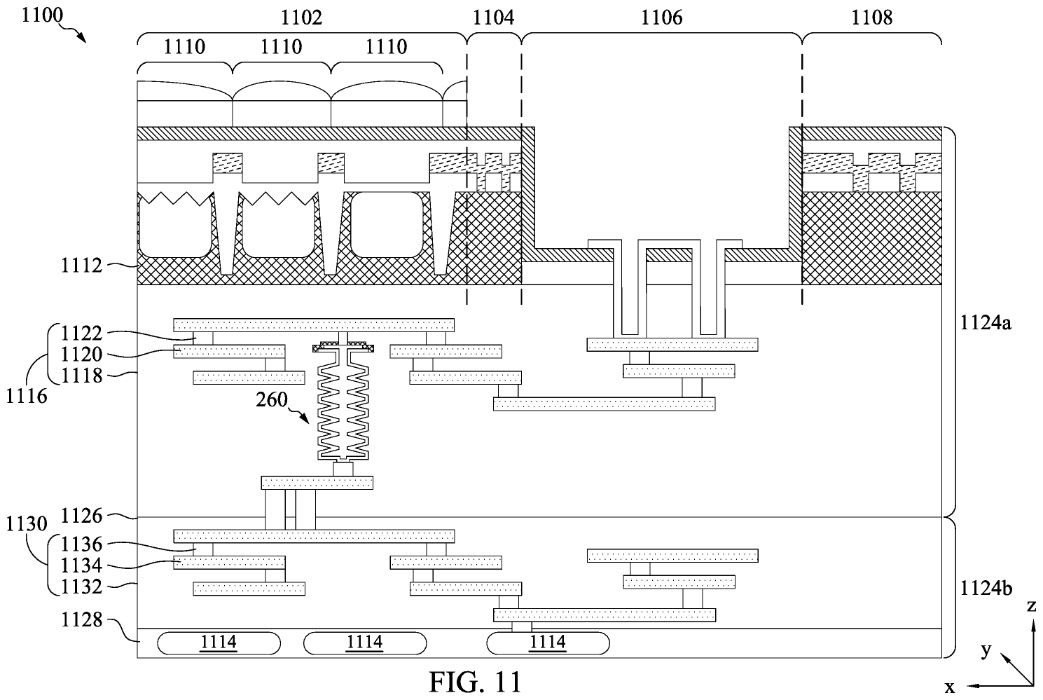

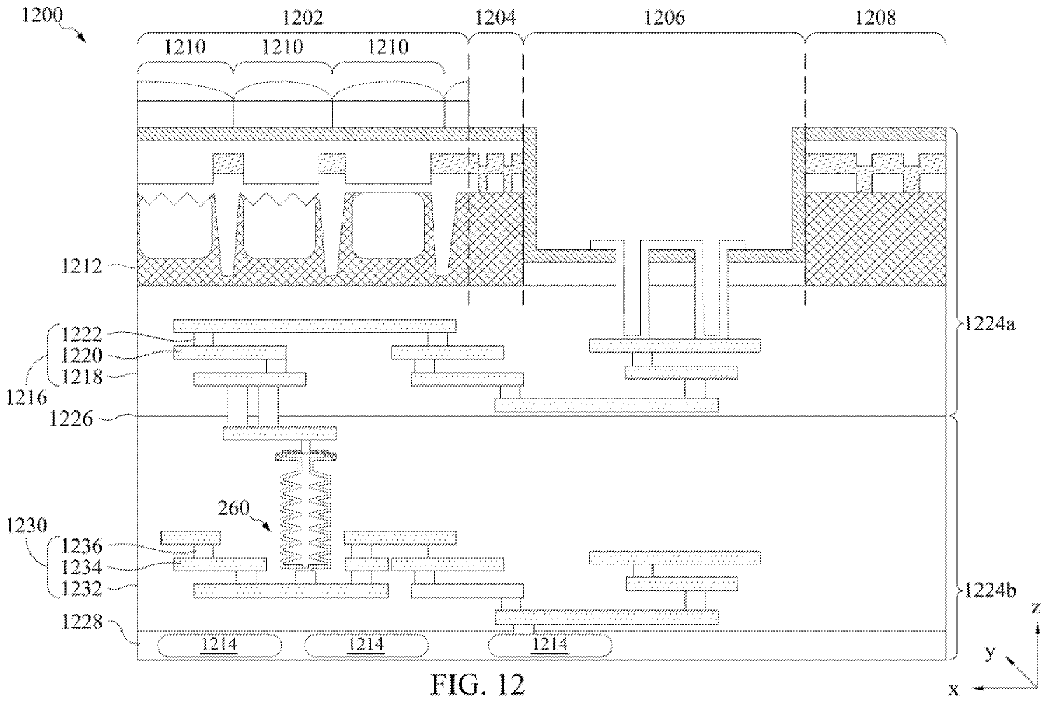

As shown in FIG. 3A, in a cross-sectional view of the deep trench capacitor structure 260, the deep trench capacitor structure 260 may be included in one or more dielectric layers. The one or more dielectric layers, and the deep trench capacitor structure 260, may be included in a semiconductor device, such as the semiconductor device 200 of FIG. 2, a semiconductor device 1000 of FIG. 10, a semiconductor device 1100 of FIG. 11, and/or a semiconductor device 1200 of FIG. 12, among other examples.

The one or more dielectric layers may include, for example, a plurality of interlayer dielectric (ILD) layers 302a-302c, a plurality of ESLs 304a-304c, a first plurality of dielectric layers 306a-306g, and/or a second plurality of dielectric layers 308a-308g, among other examples. The ILD layers 302a-302c, the first plurality of dielectric layers 306a-306g, and/or the second plurality of dielectric layers 308a-308g may correspond to one or more of the dielectric layers 214, 218, 222, and/or 226 included in the semiconductor device 200 of FIG. 2. Additionally and/or alternatively, ILD layers 302-302c, the first plurality of dielectric layers 306a-306g, and/or the second plurality of dielectric layers 308a-308g may correspond to one or more of the dielectric layers included in another semiconductor device described herein. The ESLs 304a-304c may correspond to one or more of the ESLs 216, 220, and/or 224 included in the semiconductor device 200. Additionally and/or alternatively, one or more of the ESLs 304a-304c may correspond to one or more ESLs in another semiconductor device described herein.

The first plurality of dielectric layers 306a-306g and the second plurality of dielectric layers 308a-308g may be arranged in an alternating configuration in a z-direction as shown in FIG. 3A. The first plurality of dielectric layers 306a-306g and the second plurality of dielectric layers 308a-308g may extend in an x-direction and in a y-direction, which are approximately perpendicular with the z-direction. The first plurality of dielectric layers 306a-306g may be formed of a first material (or a first combination of materials) and the second plurality of dielectric layers 308a-308g may be formed of a second material (or a second combination of materials), where the first material (or the first combination of materials) and the second material (or the second combination of materials) are different material(s).

As further shown in FIG. 3A, the deep trench capacitor structure 260 may extend through the first plurality of dielectric layers 306a-306g and through the second plurality of dielectric layers 308a-308g. The deep trench capacitor structure 260 may include a central portion 312 that extends in the z-direction through the first plurality of dielectric layers 306a-306g and through the second plurality of dielectric layers 308a-308g. The deep trench capacitor structure 260 may further include a plurality of fin portions 310 that extend laterally outward from the central portion in the x-direction and/or in the y-direction. The plurality of fin portions 310 may primarily extend into the first plurality of dielectric layers 306a-306g such that the fin portions 310 are elongated portions that extend outward from the central portion 312.

As further shown in FIG. 3A, the first conductive layer 262, the insulator layer 264, and the second conductive layer 266 may conform to the shape of the fin portions 310, which increases the surface area of the first conductive layer 262, the insulator layer 264, and the second conductive layer 266 may conform to the shape of the fin portions 310 relative to a deep trench capacitor structure that does not include the fin portions 310. The increased surface area provides increased capacitance for the deep trench capacitor structure 260 relative to a deep trench capacitor structure of a similar depth that does not include the fin portions 310.

In some implementations, at least a subset of the plurality of fin portions 310 have angled walls such that the subset of the plurality of fin portions 310 taper between the central portion 312 and ends of the subset of the plurality of fin portions 310, as shown in FIG. 3A. In some implementations, at least a subset of the plurality of fin portions 310 have approximately parallel walls such that the subset of the plurality of fin portions 310 are approximately square-shaped or rectangular.

As further shown in FIG. 3A, the deep trench capacitor structure 260 includes a bottom contact region 314 that extends through the ESL 304a. The first conductive layer 262 may contact and may be electrically connected with the bottom metal contact 268 through the bottom contact region 314. In some implementations, the central portion 312 may be formed such that the central portion 312 includes a plurality of bottom contact regions 314 that are electrically connected with the bottom metal contact 268. The second conductive layer 266 may be electrically connected with the top metal contact 270 in a top contact region 316.

FIGS. 3B-3D illustrate example top-down view configurations for the fin portions 310 and the central portion 312 of the deep trench capacitor structure 260. In an example illustrated in a top-down view in FIG. 3B, the central portion 312 of the deep trench capacitor structure 260 is approximately square-shaped, and the fin portions 310 extend laterally outward from the central portion 312 in the x-direction such that the fin portions 310 are approximately rectangular in the top-down view.

In an example illustrated in a top-down view in FIG. 3C, the central portion 312 of the deep trench capacitor structure 260 is approximately rectangular, and the fin portions 310 extend laterally outward from the central portion 312 in the x-direction such that the fin portions 310 are approximately rectangular in the top-down view.

In an example illustrated in a top-down view in FIG. 3D, the central portion 312 of the deep trench capacitor structure 260 is approximately square-shaped, and the fin portions 310 extend laterally outward from the central portion 312 in the x-direction and in the y-direction such that the fin portions 310 are approximately square-shaped in the top-down view. Other configurations for the fin portions 310 and the central portion 312 are within the scope of the present disclosure.

As indicated above, FIGS. 3A-3D are provided as examples. Other examples may differ from what is described with regard to FIGS. 3A-3D.

FIGS. 4A-4J are diagrams of an example implementation 400 of forming a deep trench capacitor structure 260 having a plurality of fin portions 310 described herein.

Turning to FIG. 4A, one or more of the semiconductor processing operations may be performed in connection with one or more dielectric layers. The one or more dielectric layers may be included in a semiconductor device, such as the semiconductor device 200 of FIG. 2, a semiconductor device 1000 of FIG. 10, a semiconductor device 1100 of FIG. 11, and/or a semiconductor device 1200 of FIG. 12, among other examples.

The one or more dielectric layers may include, for example, an ILD layer 302a, a plurality of ESLs 304a and 304b, a first plurality of dielectric layers 306a-306g, and/or a second plurality of dielectric layers 308a-308g, among other examples. The deposition tool 102 may deposit the ILD layer 302a, the plurality of ESLs 304a and 304b, the first plurality of dielectric layers 306a-306g, and/or the second plurality of dielectric layers 308a-308g, in one or more PVD operations, one or more ALD operations, one or more CVD operations, one or more epitaxy operations, one or more oxidation operations, one or more deposition operations of another type described in connection with FIG. 1, and/or one or more other suitable deposition operations. In some implementations, the planarization tool 110 planarizes the ILD layer 302a, the plurality of ESLs 304a and 304b, the first plurality of dielectric layers 306a-306g, and/or the second plurality of dielectric layers 308a-308g, after the deposition tool 102 deposits the ILD layer 302a, the plurality of ESLs 304a and 304b, the first plurality of dielectric layers 306a-306g, and/or the second plurality of dielectric layers 308a-308g.

The first plurality of dielectric layers 306a-306g and the second plurality of dielectric layers 308a-308g may each have a thickness that is included in a range of approximately 0.02 microns to approximately 0.17 microns. However, other values for the range are within the scope of the present disclosure. In some implementations, a thickness of the second plurality of dielectric layers 308a-308g is greater relative to a thickness of the first plurality of dielectric layers 306a-306g. A quantity of the first plurality of dielectric layers 306a-306g and a quantity of the second plurality of dielectric layers 308a-308g may each be included in a range of greater than 1 layer to 10 layers. However, other values for the range are within the scope of the present disclosure. In general, the quantity of the first plurality of dielectric layers 306a-306g and the quantity of the second plurality of dielectric layers 308a-308g may be selected based on a quantity of fin portions 310 that are to be formed for the deep trench capacitor structure 260.

As shown in FIG. 4B, a trench 402 may be formed through a plurality of dielectric layers such that the trench extends in the z-direction through the plurality of dielectric layers. For example, the trench 402 may extend through the ESLs 304a and 304b, through the first plurality of dielectric layers 306a-306g, and through the second plurality of dielectric layers 308a-308g. The trench 402 may extend to the bottom metal contact 268 such that the bottom metal contact 268 is exposed through the trench 402.

In some implementations, a pattern in a photoresist layer is used to etch the ESLs 304a and 304b, the first plurality of dielectric layers 306a-306g, and the second plurality of dielectric layers 308a-308g to form the trench 402. In these implementations, the deposition tool 102 forms the photoresist layer on the ESL 304b. The exposure tool 104 exposes the photoresist layer to a radiation source to pattern the photoresist layer. The developer tool 106 develops and removes portions of the photoresist layer to expose the pattern. The etch tool 108 etches the ESLs 304a and 304b, the first plurality of dielectric layers 306a-306g, and the second plurality of dielectric layers 308a-308g based on the pattern to form the trench 402 in a first etch operation. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, the etch tool 108 performs a plurality of etch cycles in the first etch operation to form the trench 402. In some implementations, the ESL 304b is used as a hard mask layer that is patterned for etching the ESL 304a, the first plurality of dielectric layers 306a-306g, and the second plurality of dielectric layers 308a-308g. In some implementations, a photoresist removal tool removes the remaining portions of the photoresist layer (e.g., using a chemical stripper, plasma ashing, and/or another technique).

As shown in FIG. 4C, the first plurality of dielectric layers 306a-306g, and/or the second plurality of dielectric layers 308a-308g may be etched through the trench 402 to form lateral extension regions 404. The lateral extension regions 404 laterally extend from the trench 402 into the first plurality of dielectric layers 306a-306g, and/or into the second plurality of dielectric layers 308a-308g in the x-direction and/or in the y-direction (e.g., both of which are approximately perpendicular to the z-direction). The etch tool 108 may perform one or more etch cycles in a second etch operation (e.g., after the first etch operation described above in connection with FIG. 4B) to form the lateral extension regions 404.

In some implementations, the first plurality of dielectric layers 306a-306g and a second plurality of dielectric layers 308a-308g may be etched using a buffered oxide etch (BOE) etch technique, in which a BOE etchant that includes a combination of hydrofluoric acid (HF) and ammonium fluoride (NH₄F). The concentration of hydrofluoric acid in the BOE etchant may be approximately 1% by volume of approximately 49% strength hydrofluoric acid. However, other values are within the scope of the present disclosure. The concentration of ammonium fluoride in the BOE etchant may be approximately 6% by volume of approximately 40% strength ammonium fluoride. However, other values are within the scope of the present disclosure. In some implementations, the BOE etchant further includes deionized water (DIW). The concentration of deionized water in the BOE etchant may be approximately 7% by volume of approximately 40% strength ammonium fluoride.

An etch rate of the BOE etchant for the first plurality of dielectric layers 306a-306g may be greater relative to an etch rate of the BOE etchant for the second plurality of dielectric layers 308a-308g, which results in a greater amount of lateral etching for the first plurality of dielectric layers 306a-306g relative to an amount of lateral etching for the second plurality of dielectric layers 308a-308g. In this way, the lateral extension regions 404 may extend primarily into the first plurality of dielectric layers 306a-306g, and fin tips 406 are formed in the second plurality of dielectric layers 308a-308g. The fin tips 406 are ends of the second plurality of dielectric layers 308a-308g that extend inward toward a center 408 of the trench 402 from the first plurality of dielectric layers 306a-306g.

Additionally and/or alternatively, a hydrofluoric acid (HF) etchant may be used to etch the first plurality of dielectric layers 306a-306g and a second plurality of dielectric layers 308a-308g to form the lateral extension regions 404. The HF etchant may include hydrofluoric acid that is diluted in deionized water (DIW). An etch rate of the HF etchant for the first plurality of dielectric layers 306a-306g may be greater relative to an etch rate of the HF etchant for the second plurality of dielectric layers 308a-308g, which results in a greater amount of lateral etching for the first plurality of dielectric layers 306a-306g relative to an amount of lateral etching for the second plurality of dielectric layers 308a-308g. In this way, the lateral extension regions 404 may extend primarily into the first plurality of dielectric layers 306a-306g, and fin tips 406 are formed in the second plurality of dielectric layers 308a-308g.

A combination of materials for the first plurality of dielectric layers 306a-306g and the second plurality of dielectric layers 308a-308g, and the etchant that is used to etch the first plurality of dielectric layers 306a-306g and the second plurality of dielectric layers 308a-308g to form the extension regions 404, may be selected to generally achieve a greater etch rate for the first plurality of dielectric layers 306a-306g relative to the etch rate for the second plurality of dielectric layers 308a-308g.

As an example, a BOE etchant may be used in combination with phosphosilicate glass (PSG) layers as the first plurality of dielectric layers 306a-306g and borosilicate glass (BSG) layers as the second plurality of dielectric layers 308a-308g. The etch rate of the BOE etchant for the PSG layers may be greater relative for the BSG layers, which enables the lateral extension regions 404 to laterally extend into the first plurality of dielectric layers 306a-306g. The etch rate for the BOE etchant may be based on a boron concentration in the first plurality of dielectric layers 306a-306g and in the second plurality of dielectric layers 308a-308g. In particular, the etch rate for the BOE etchant may decrease as boron concentration increases, which results in the BSG layers (e.g., the second plurality of dielectric layers 308a-308g) having a lesser etch rate relative to the PSG layers (e.g., the first plurality of dielectric layers 306a-306g).

In some implementations, the etch rate of the BOE etchant for the BSG layers may be included in a range of approximately 420 angstroms per minute to approximately 635 angstroms per minute. However, other values for the range are within the scope of the present disclosure. In some implementations, the etch rate of the BOE etchant for the PSG layers may be included in a range of approximately 3930 angstroms per minute to approximately 8400 angstroms per minute. However, other values for the range are within the scope of the present disclosure.

As another example, a BOE etchant may be used in combination with undoped silicate glass (USG) layers as the first plurality of dielectric layers 306a-306g and borophosphosilicate glass (BPSG) layers as the second plurality of dielectric layers 308a-308g. The etch rate of the BOE etchant for the USG layers may be greater relative for the BPSG layers, which enables the lateral extension regions 404 to laterally extend into the first plurality of dielectric layers 306a-306g. As another example, a BOE etchant may be used in combination with undoped silicate glass (USG) layers as the first plurality of dielectric layers 306a-306g and borosilicate glass (BSG) layers as the second plurality of dielectric layers 308a-308g. The etch rate of the BOE etchant for the USG layers may be greater relative for the BSG layers, which enables the lateral extension regions 404 to laterally extend into the first plurality of dielectric layers 306a-306g.

In some implementations, the etch rate of the BOE etchant for the BPSG layers may be included in a range of approximately 840 angstroms per minute to approximately 1480 angstroms per minute. However, other values for the range are within the scope of the present disclosure. In some implementations, the etch rate of the BOE etchant for the USG layers may be included in a range of approximately 1330 angstroms per minute to approximately 6000 angstroms per minute. However, other values for the range are within the scope of the present disclosure.

As another example, a BOE etchant may be used in combination with phosphosilicate glass (PSG) layers as the first plurality of dielectric layers 306a-306g and borophosphosilicate glass (BPSG) layers as the second plurality of dielectric layers 308a-308g. The etch rate of the BOE etchant for the PSG layers may be greater relative for the BPSG layers, which enables the lateral extension regions 404 to laterally extend into the first plurality of dielectric layers 306a-306g.

As another example, an HF etchant may be used in combination with borophosphosilicate glass (BPSG) as the first plurality of dielectric layers 306a-306g and undoped silicate glass (USG) layers as the second plurality of dielectric layers 308a-308g. The etch rate of the HF etchant for the BPSG layers may be greater relative for the USG layers, which enables the lateral extension regions 404 to laterally extend into the first plurality of dielectric layers 306a-306g.

As another example, an HF etchant may be used in combination with phosphosilicate glass (PSG) layers as the first plurality of dielectric layers 306a-306g and undoped silicate glass (USG) layers as the second plurality of dielectric layers 308a-308g. The etch rate of the HF etchant for the PSG layers may be greater relative for the USG layers, which enables the lateral extension regions 404 to laterally extend into the first plurality of dielectric layers 306a-306g.

As another example, an HF etchant may be used in combination with borophosphosilicate glass (BPSG) layers as the first plurality of dielectric layers 306a-306g and borosilicate glass (BSG) layers as the second plurality of dielectric layers 308a-308g. The etch rate of the HF etchant for the BPSG layers may be greater relative for the BSG layers, which enables the lateral extension regions 404 to laterally extend into the first plurality of dielectric layers 306a-306g.

As another example, an HF etchant may be used in combination with phosphosilicate glass (PSG) layers as the first plurality of dielectric layers 306a-306g and borosilicate glass (BSG) layers as the second plurality of dielectric layers 308a-308g. The etch rate of the HF etchant for the PSG layers may be greater relative for the BSG layers, which enables the lateral extension regions 404 to laterally extend into the first plurality of dielectric layers 306a-306g.

In some implementations, a concentration of hydrofluoric acid in the HF etchant may be included in a range of approximately 1% by weight of the HF etchant (e.g., approximately 50:1 ratio of deionized water to hydrofluoric acid) to approximately 16% by weight of the HF etchant (e.g., approximately 2:1 ratio of deionized water to hydrofluoric acid) to achieve a sufficiently large difference in etch rate (e.g., a sufficiently high etch selectivity) between the first plurality of dielectric layers 306a-306g and the second plurality of dielectric layers 308a-308g. However, other values for the range are within the scope of the present disclosure. In some implementations, the etch rate of the HF etchant for the first plurality of dielectric layers 306a-306g may be approximately 3 times greater to approximately 5.3 times greater relative to the etch rate of the HF etchant for the second plurality of dielectric layers 308a-308g. However, other values for the range are within the scope of the present disclosure. The etch rate for the HF etchant may be greater for greater concentrations of boron and/or phosphor and lesser for lesser concentrations of boron and/or phosphor.

The time duration of the second etch operation to form the lateral extension regions 404 may be selected to provide sufficient time to fully etch the lateral extension regions 404 while minimizing over etching. As an example, in implementations in which a BOE etchant is used, the time duration for the second etch operation may be included in a range of approximately 10 seconds to approximately 30 seconds to provide sufficient time to fully etch the lateral extension regions 404 while minimizing over etching. However, other values for the range are within the scope of the present disclosure. As another example, in implementations in which an HF etchant is used, the time duration for the second etch operation may be included in a range of approximately 10 seconds to approximately 60 seconds to provide sufficient time to fully etch the lateral extension regions 404 while minimizing over etching. However, other values for the range are within the scope of the present disclosure.

As further shown in FIG. 4C, the lateral extension regions 404 and/or the fin tips 406 may have one or more dimensions, which correspond to dimensions of the fin portions 310 of the deep trench capacitor structure 260 that is formed in the trench 402 and in the lateral extension regions 404. As an example, a dimension D1 may correspond to a lateral depth of a fin tip 406 associated with a lateral extension region 404. In some implementations, the dimension D1 is included in a range of approximately 0.13 microns to approximately 0.32 microns. However, other values for the range are within the scope of the present disclosure.

As another example, a dimension D2 may correspond to a lateral depth of a lateral extension region 404 relative to an approximate center 408 of the trench 402. In some implementations, the dimension D2 is included in a range of approximately 0.32 microns to approximately 0.38 microns. However, other values for the range are within the scope of the present disclosure. In some implementations, a ratio of the dimension D1 to the Dimension D2 is included in a range of approximately 2:5 to approximately 4:5 to achieve a sufficient high capacitance for the deep trench capacitor structure 260. However, other values for the range are within the scope of the present disclosure.

As another example, a dimension D3 may correspond to a tip width of a fin tip 406. In some implementations, the dimension D3 may be included in a range of greater than 0 microns to approximately equal to the thickness of the dielectric layer in which the fin tip 406 is formed. However, other values for the range are within the scope of the present disclosure.

As another example, a dimension D4 may correspond to a tip angle of a fin tip 406. In some implementations, the dimension D4 is included in a range of approximately 10 degrees to approximately 90 degrees to enable formation of the lateral extension regions while achieving a sufficient high capacitance for the deep trench capacitor structure 260. However, other values for the range are within the scope of the present disclosure.

Another example dimension D5 may include a spacing of adjacent fin tips 406. In some implementations, the dimension D5 is included in a range of approximately 0.15 microns to approximately 0.2 microns to enable formation of the lateral extension regions while achieving a sufficient high capacitance for the deep trench capacitor structure 260. However, other values for the range are within the scope of the present disclosure.

As shown in FIG. 4D, a first conductive layer 262 of a deep trench capacitor structure 260 is formed in the trench 402, on walls of the plurality of lateral extension regions 404, and in a bottom contact region. The first conductive layer 262 may also be formed on a top surface of the ESL 304b. The deposition tool 102 and/or the plating tool 112 may conformally deposit the first conductive layer 262 in a CVD operation, a PVD operation, an ALD operation, an electroplating operation, another deposition operation described above in connection with FIG. 1, and/or another suitable deposition operation. In some implementations, a seed layer is first deposited, and the first conductive layer 262 is deposited on the seed layer.

The first conductive layer 262 may correspond to the capacitor bottom metal layer of the deep trench capacitor structure 260. The first conductive layer 262 may be formed over and/or on the bottom metal contact 268 such that the first conductive layer 262 is electrically and/or physically connected with the bottom metal contact 268. The first conductive layer 262 may also correspond to a portion of the fin portions 310 of the deep trench capacitor structure 260.

As shown in FIG. 4E, an insulator layer 264 is formed over and/or on the first conductive layer 262 in the trench 402, in a bottom contact region, and in the fin portions 310 of the deep trench capacitor structure 260. The deposition tool 102 may conformally deposit the insulator layer 264 in a PVD operation, an ALD operation, a CVD operation, an epitaxy operation, an oxidation operation, another type of deposition operation described in connection with FIG. 1, and/or another suitable deposition operation. In some implementations, the insulator layer 264 is formed to a thickness that is included in a range of approximately 5 nanometers to approximately 15 nanometers to satisfy a breakdown voltage (V_{bd}) parameter for the deep trench capacitor structure 260. However, other values for the range are within the scope of the present disclosure.

As shown in FIG. 4F, a second conductive layer 266 of the deep trench capacitor structure 260 is formed over and/or on the insulator layer 264. The deposition tool 102 and/or the plating tool 112 may conformally deposit the second conductive layer 266 in a CVD operation, a PVD operation, an ALD operation, an electroplating operation, another deposition operation described above in connection with FIG. 1, and/or another suitable deposition operation. In some implementations, a seed layer is first deposited, and the second conductive layer 266 is deposited on the seed layer.

The second conductive layer 266 may correspond to the capacitor top metal layer of the deep trench capacitor structure 260. The second conductive layer 266 may be formed to fully fill in the remaining volume of the trench 402, a bottom contact region, and the fin portions 310.

As shown in FIG. 4G, a capping layer 272 is formed over and/or on the ESL 304b. Moreover, the capping layer 272 is formed over and/or on exposed portions of the first conductive layer 262 and exposed portions of the second conductive layer 266 above the ESL 304b. The deposition tool 102 may deposit the capping layer 272 in a PVD operation, an ALD operation, a CVD operation, an epitaxy operation, an oxidation operation, another type of deposition operation described in connection with FIG. 1, and/or another suitable deposition operation. In some implementations, the deposition tool 102 deposits the capping layer 272 in a blanket deposition operation, and the etch tool 108 etches the capping layer 272 to remove portions of the capping layer 272 such that the capping layer 272 remains on the exposed portions of the first conductive layer 262 and exposed portions of the second conductive layer 266 above the ESL 304b.

As shown in FIG. 4H, one or more additional dielectric layers are formed over and/or on the ESL 304b and/or over and/or on the capping layer 272. The deposition tool 102 may deposit an ILD layer 302b, an ILD layer 302c, and/or an ESL 304c in a PVD operation, an ALD operation, a CVD operation, an epitaxy operation, an oxidation operation, another type of deposition operation described in connection with FIG. 1, and/or another suitable deposition operation. In some implementations, the planarization tool 110 planarizes the ILD layer 302b, the ILD layer 302c, and/or the ESL 304c after the deposition tool 102 deposits the ILD layer 302b, the ILD layer 302c, and/or the ESL 304c.

As shown in FIG. 4I, a trench 410 may be formed through the ILD layer 302c, the ESL 304c, the ILD layer 302b, and/or the ESL 304b to expose a top surface of the second conductive layer 266. In some implementations, the trench 410 may be formed into a portion of the second conductive layer 266 to ensure that the ILD layer 302c, the ESL 304c, the ILD layer 302b, and/or the ESL 304b are fully etched through.

In some implementations, a pattern in a photoresist layer is used to etch the ILD layer 302c, the ESL 304c, the ILD layer 302b, and/or the ESL 304b to form the trench 410. In these implementations, the deposition tool 102 forms the photoresist layer on the ILD layer 302c. The exposure tool 104 exposes the photoresist layer to a radiation source to pattern the photoresist layer. The developer tool 106 develops and removes portions of the photoresist layer to expose the pattern. The etch tool 108 etches the ILD layer 302c, the ESL 304c, the ILD layer 302b, and/or the ESL 304b based on the pattern to form the trench 410. In some implementations, the etch operation includes a plasma etch operation, a wet chemical etch operation, and/or another type of etch operation. In some implementations, a photoresist removal tool removes the remaining portions of the photoresist layer (e.g., using a chemical stripper, plasma ashing, and/or another technique). In some implementations, a hard mask layer is used as an alternative technique for etching the ILD layer 302c, the ESL 304c, the ILD layer 302b, and/or the ESL 304b based on a pattern. In some implementations, a photoresist removal tool removes the remaining portions of the photoresist layer (e.g., using a chemical stripper, plasma ashing, and/or another technique).

As shown in FIG. 4J, a top metal contact 270 is formed in the trench 410 such that the top metal contact 270 lands on the second conductive layer 266. The deposition tool 102 and/or the plating tool 112 may deposit the top metal contact 270 in a CVD operation, a PVD operation, an ALD operation, an electroplating operation, another deposition operation described above in connection with FIG. 1, and/or another suitable deposition operation. In some implementations, a seed layer is first deposited, and the top metal contact 270 is deposited on the seed layer. In some implementations, the planarization tool 110 planarizes the top metal contact 270 after the deposition tool 102 and/or the plating tool 112 deposits the top metal contact 270.

As indicated above, FIGS. 4A-4J are provided as an example. Other examples may differ from what is described with regard to FIGS. 4A-4J.

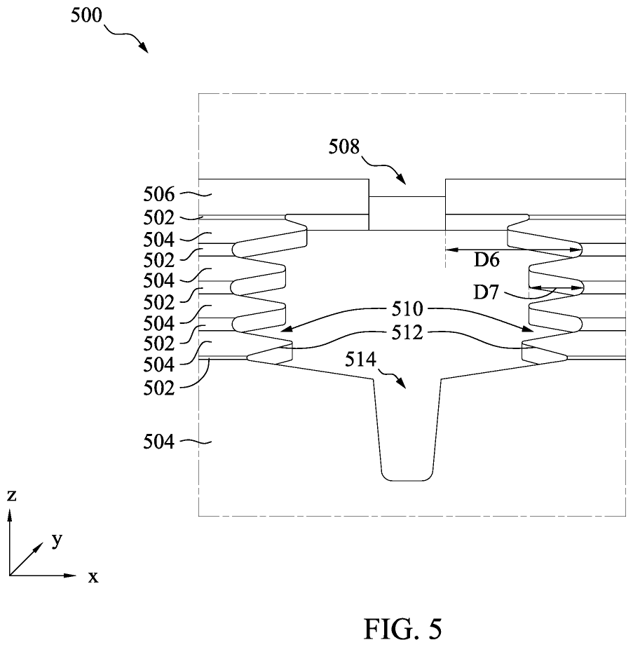

FIG. 5 is a diagram of an example implementation 500 of a trench and lateral extension regions in which a deep trench capacitor structure 260 having a plurality of fin portions 310 described herein may be formed. As shown in FIG. 5, the trench and the lateral extension regions may be formed in a plurality of dielectric layers, such as a first plurality of dielectric layers 502 and a second plurality of dielectric layers 504. In some implementations, the first plurality of dielectric layers 502 may correspond to the first plurality of dielectric layers 306a-306g. In some implementations, the second plurality of dielectric layers 504 may correspond to the second plurality of dielectric layers 308a-308g. An ESL 506 may be used to form the trench and lateral extension regions.

As shown in FIG. 5, the first plurality of dielectric layers 502 and the second plurality of dielectric layers 504 may extend in the x-direction and may alternate in the z-direction. The first plurality of dielectric layers 502 may include borophosphosilicate glass (BPSG) layers, and the second plurality of dielectric layers 504 may include undoped silicate glass (USG) layers.

As further shown in FIG. 5, a trench 508 may be formed in and/or through the first plurality of dielectric layers 502 and the second plurality of dielectric layers 504. The trench 508 may be formed by etching the first plurality of dielectric layers 502 and the second plurality of dielectric layers 504 using similar etching techniques as described in connection with FIG. 4B and/or elsewhere herein.

As further shown in FIG. 5, a plurality of lateral extension regions 510 may be formed through the trench 508 and into the first plurality of dielectric layers 502 and the second plurality of dielectric layers 504. The lateral extension regions 510 may be formed to a greater lateral depth in the first plurality of dielectric layers 502 relative to the lateral depth in the second plurality of dielectric layers 504, thereby resulting in the formation of fin tips 512 in the second plurality of dielectric layers 504. The trench 508 may extend into a bottom dielectric layer of the second plurality of dielectric layers 504, in which a bottom contact region 514 is formed.

In some implementations, the first plurality of dielectric layers 502 and a second plurality of dielectric layers 504 may be etched using a buffered oxide etch (BOE) etch technique, in which a BOE etchant that includes a combination of hydrofluoric acid (HF) and ammonium fluoride (NH₄F). In some implementations, the BOE etchant further includes deionized water (DIW). The second plurality of dielectric layers 504 may be formed to a greater thickness relative to the first plurality of dielectric layers 502 to facilitate formation of lateral extension regions that extend into the first plurality of dielectric layers 502. In particular, the greater thickness of the second plurality of dielectric layers 504 relative to the thickness of the first plurality of dielectric layers 502 may result in a greater etch back for the first plurality of dielectric layers 502 relative to the etch back of the second plurality of dielectric layers 504, which results in the formation of the lateral extension regions 510 in the first plurality of dielectric layers 502.

Alternatively, phosphosilicate silicon glass (PSG) layers may be used for the first plurality of dielectric layers 502, and borosilicate glass (BSG) layers may be used for the second plurality of dielectric layers 504, to achieve formation of the lateral extension regions 510. The concentration of hydrofluoric acid, ammonium fluoride, and/or deionized water in the BOE etchant may be selected such that the BOE etchant etches the PSG layers and the BSG layers at different etch rates. For example, the BOE etchant may etch the PSG layers at a faster etch rate relative to the etch rate of the BSG layers, which results in the formation of the lateral extension regions 510 in the PSG layers.

As further shown in FIG. 5, a lateral extension region 510 may extend into a first dielectric layer 502 to a dimension D6, which may be a distance from an opening of the trench 508 in the ESL 506. Moreover, a lateral extension region 510 may extend into a first dielectric layer 502 to a dimension D7, which may be a distance from a fin tip 512 in a second dielectric layer 504. A ratio of the dimension D7 to the dimension D6 may be referred to as a tip ratio, and may be included in a range of approximately 40% to approximately 80%. However, other values for the range are within the scope of the present disclosure.

As indicated above, FIG. 5 is provided as an example. Other examples may differ from what is described with regard to FIG. 5.

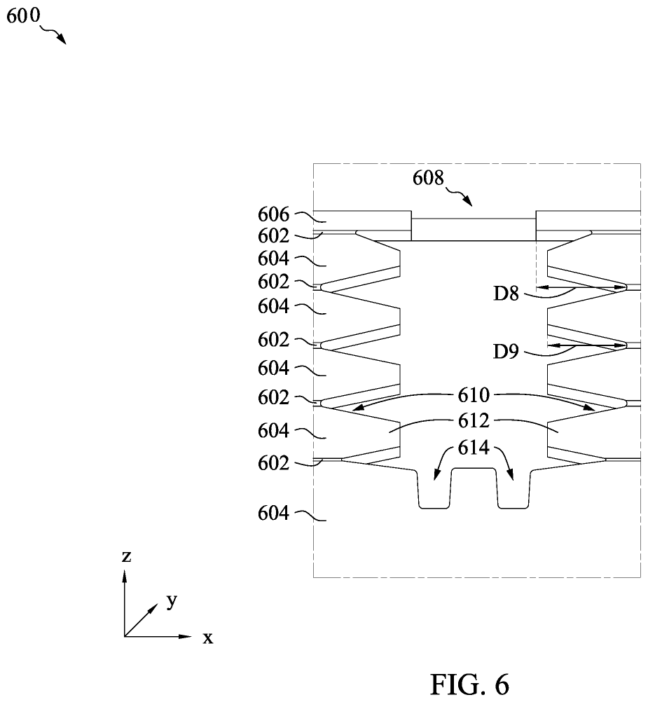

FIG. 6 is a diagram of an example implementation 600 of a trench and lateral extension regions in which a deep trench capacitor structure 260 having a plurality of fin portions 310 described herein may be formed. As shown in FIG. 6, the trench and the lateral extension regions may be formed in a plurality of dielectric layers, such as a first plurality of dielectric layers 602 and a second plurality of dielectric layers 604 that alternate in the z-direction with the first plurality of dielectric layers 602. In some implementations, the first plurality of dielectric layers 602 may correspond to the first plurality of dielectric layers 306a-306g. In some implementations, the second plurality of dielectric layers 604 may correspond to the second plurality of dielectric layers 308a-308g. An ESL 606 may be used to form the trench and lateral extension regions.

As shown in FIG. 6, the first plurality of dielectric layers 602 and the second plurality of dielectric layers 604 may extend in the x-direction and may alternate in the z-direction. The first plurality of dielectric layers 602 may include undoped silicate glass (USG) layers, and the second plurality of dielectric layers 604 may include borophosphosilicate glass (BPSG) layers.

As further shown in FIG. 6, a trench 608 may be formed in and/or through the first plurality of dielectric layers 602 and the second plurality of dielectric layers 604. The trench 608 may be formed by etching the first plurality of dielectric layers 602 and the second plurality of dielectric layers 604 using similar etching techniques as described in connection with FIG. 4B and/or elsewhere herein.

As further shown in FIG. 6, a plurality of lateral extension regions 610 may be formed through the trench 608 and into the first plurality of dielectric layers 602 and the second plurality of dielectric layers 604. The lateral extension regions 610 may be formed to a greater lateral depth in the first plurality of dielectric layers 602 relative to the lateral depth in the second plurality of dielectric layers 604, thereby resulting in the formation of fin tips 612 in the second plurality of dielectric layers 604. The trench 608 may extend into a bottom dielectric layer of the plurality of dielectric layers 604, in which a plurality of bottom contact regions 614 are formed.

In some implementations, the first plurality of dielectric layers 602 and a second plurality of dielectric layers 604 may be etched using a buffered oxide etch (BOE) etch technique, in which a BOE etchant that includes a combination of hydrofluoric acid (HF) and ammonium fluoride (NH₄F). In some implementations, the BOE etchant further includes deionized water (DIW). The second plurality of dielectric layers 604 may be formed to a greater thickness relative to the first plurality of dielectric layers 602 to facilitate formation of lateral extension regions that extend into the first plurality of dielectric layers 602. In particular, the greater thickness of the second plurality of dielectric layers 604 relative to the thickness of the first plurality of dielectric layers 602 may result in a greater etch rate and a greater etch back for the first plurality of dielectric layers 602 relative to the etch rate and the etch back of the second plurality of dielectric layers 604, which results in the formation of the lateral extension regions 610 in the first plurality of dielectric layers 602.

Additionally and/or alternatively, the concentration of hydrofluoric acid, ammonium fluoride, and/or deionized water in the BOE etchant may be selected such that the BOE etchant etches the USG layers (e.g., the first plurality of dielectric layers 602) and the BPSG layers (e.g., the second plurality of dielectric layers 604) at different etch rates. For example, the BOE etchant may etch the USG layers at a faster etch rate relative to the etch rate of the BPSG layers, which results in the formation of the lateral extension regions 610 in the USG layers.

Alternatively, phosphosilicate silicon glass (PSG) layers may be used for the first plurality of dielectric layers 602, and borosilicate glass (BSG) layers may be used for the second plurality of dielectric layers 604, to achieve formation of the lateral extension regions 610. The concentration of hydrofluoric acid, ammonium fluoride, and/or deionized water in the BOE etchant may be selected such that the BOE etchant etches the PSG layers and the BSG layers at different etch rates. For example, the BOE etchant may etch the PSG layers at a faster etch rate relative to the etch rate of the BSG layers, which results in the formation of the lateral extension regions 610 in the PSG layers.

As further shown in FIG. 6, a lateral extension region 610 may extend into a first dielectric layer 602 to a dimension D8, which may be a distance from an opening of the trench 608 in the ESL 606. Moreover, a lateral extension region 610 may extend into a first dielectric layer 602 to a dimension D9, which may be a distance from a fin tip 612 in a second dielectric layer 604. A ratio of the dimension D8 to the dimension D9 may be referred to as a tip ratio, and may be included in a range of approximately 40% to approximately 80%. However, other values for the range are within the scope of the present disclosure.

As indicated above, FIG. 6 is provided as an example. Other examples may differ from what is described with regard to FIG. 6.

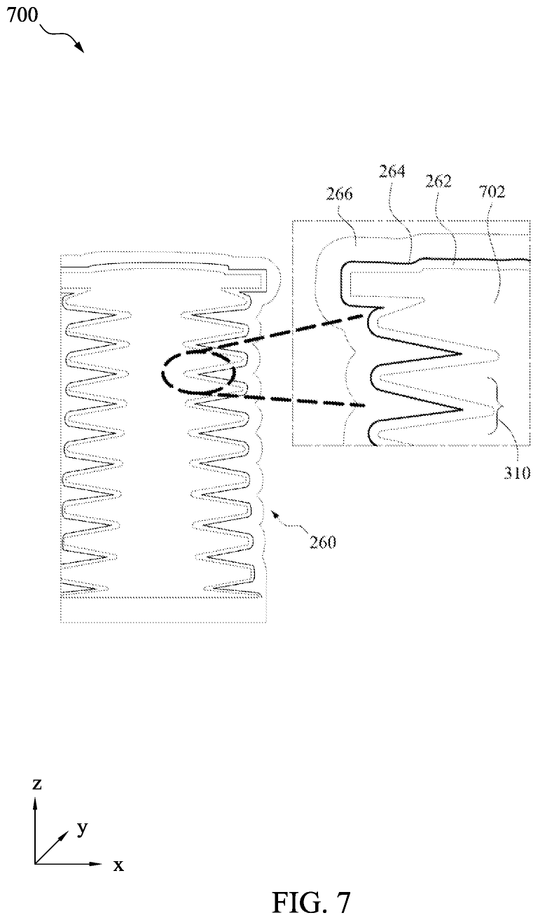

FIG. 7 is a diagram of an example implementation 700 of a deep trench capacitor structure 260 having a plurality of fin portions described herein. In the example implementation 700, the deep trench capacitor structure 260 may have an inverted configuration relative to the example implementation 300 of the deep trench capacitor structure 260 in FIG. 3A. In particular, the deep trench capacitor structure 260 illustrated in FIG. 7 may be formed around a dielectric core 702, which may include one or more dielectric layers.

The dielectric core 702 may be formed using similar etching techniques as described in connection with FIGS. 4B and 4C such that lateral extension regions extend into the dielectric core 702. For example, the dielectric core 702 may be formed by etching (e.g., by the etch tool 108) a first plurality of dielectric layers and a second plurality of dielectric layers that alternate in the z-direction with the first plurality of dielectric layers using a hydrofluoric acid (HF) etch technique and/or a buffered oxide etch (BOE) etch technique to etch the first plurality of dielectric layers and the second plurality of dielectric layers at different etch rates. The different etch rates may result from the different materials used for the first plurality of dielectric layers and the second plurality of dielectric layers, which may result in the formation of the lateral extension regions. In the example implementation 700, the first plurality of dielectric layers may include borophosphosilicate glass (BPSG), and the second plurality of dielectric layers may include undoped silicate glass (USG).

The first conductive layer 262, the insulator layer 264, and the second conductive layer 266 of the deep trench capacitor structure 260 may conform to the shape of the dielectric core 702, which results in the formation of the fin portions 310 of the deep trench capacitor structure 260. The fin portions 310 may have angled walls such that the fin portions 310 are tapered and terminate at a pointed termination point.

As indicated above, FIG. 7 is provided as an example. Other examples may differ from what is described with regard to FIG. 7.

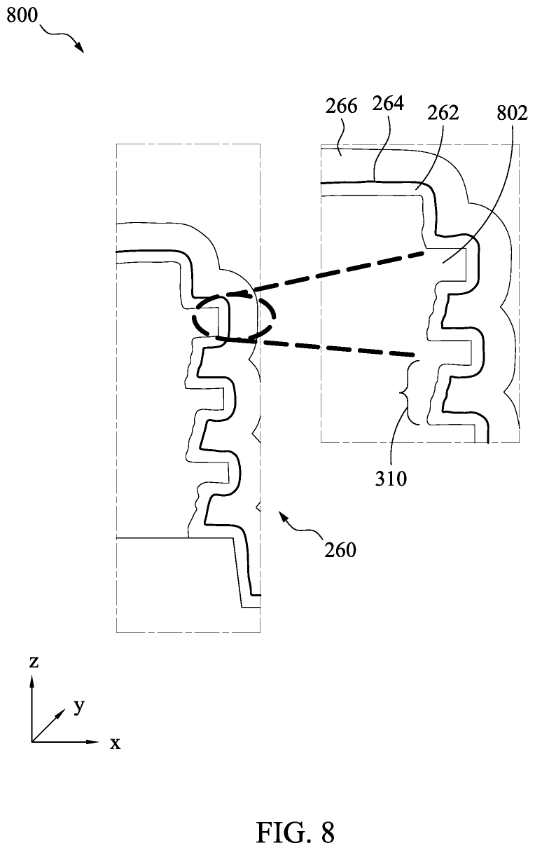

FIG. 8 is a diagram of an example implementation 800 of a deep trench capacitor structure 260 having a plurality of fin portions described herein. In the example implementation 800, the deep trench capacitor structure 260 may have an inverted configuration relative to the example implementation 300 of the deep trench capacitor structure 260 in FIG. 3A. In particular, the deep trench capacitor structure 260 illustrated in FIG. 8 may be formed around a dielectric core 802, which may include one or more dielectric layers.

The dielectric core 802 may be formed using similar etching techniques as described in connection with FIGS. 4B and 4C such that lateral extension regions extend into the dielectric core 802. For example, the dielectric core 802 may be formed by etching (e.g., by the etch tool 108) a first plurality of dielectric layers and a second plurality of dielectric layers that alternate in the z-direction with the first plurality of dielectric layers using a hydrofluoric acid (HF) etch technique and/or a buffered oxide etch (BOE) etch technique to etch the first plurality of dielectric layers and the second plurality of dielectric layers at different etch rates. The different etch rates may result from the different materials used for the first plurality of dielectric layers and the second plurality of dielectric layers, which may result in the formation of the lateral extension regions. In the example implementation 800, the first plurality of dielectric layers may include silicon carbide (SiC), and the second plurality of dielectric layers may include undoped silicate glass (USG).

The first conductive layer 262, the insulator layer 264, and the second conductive layer 266 of the deep trench capacitor structure 260 may conform to the shape of the dielectric core 802, which results in the formation of the fin portions 310 of the deep trench capacitor structure 260. The fin portions 310 may have approximately straight and non-angled walls such that the fin portions 310 are square-shaped and terminate at a flat-faced termination point. In some implementations, the flat-faced termination point may be angled (e.g., may be greater or less than approximately 90 degrees) in the z-direction.

As indicated above, FIG. 8 is provided as an example. Other examples may differ from what is described with regard to FIG. 8.

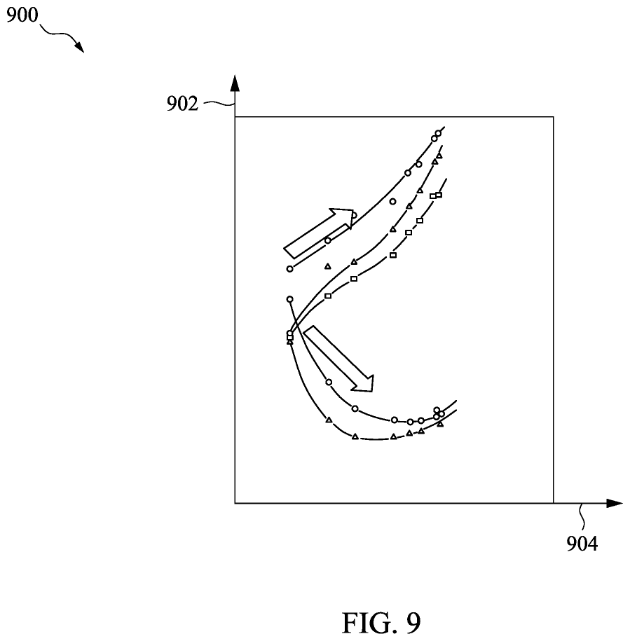

FIG. 9 is a diagram of an example implementation 900 of etch rates for forming lateral extension regions described herein. The lateral extension regions (e.g., lateral extension regions 404, 510, and/or 610) may laterally extend from a trench (e.g., a trench 402, 508, and/or 608) in which a deep trench capacitor structure 260 having a plurality of fin portions 310 is to be formed.

As shown in FIG. 9, an etch rate 902 for the etch operations described in connection with FIGS. 4C, 5, and/or 6, among other examples, may be based on a boron (B) concentration 904 in the dielectric layers (e.g., dielectric layers 216-226, 306a-306g, 308a-308g, 502, 504, 602, 604, among other examples) in which the lateral extension regions are formed. When a BOE technique is used, the etch rate of the dielectric layers may be greater for lesser boron concentrations 904 in the dielectric layers, and may be lesser for greater boron concentrations 904 in the dielectric layers. When an HF etch technique is used, the etch rate of the dielectric layers may be lesser for lesser boron concentrations 904 in the dielectric layers, and may be greater for greater boron concentrations 904 in the dielectric layers. Accordingly, the shape and/or size of the lateral extension regions may be achieved through selecting a particular combination of materials for the dielectric layers and etchants for the etch operations to form the lateral extension regions.

As indicated above, FIG. 9 is provided as an example. Other examples may differ from what is described with regard to FIG. 9.

FIG. 10 is a diagram of an example semiconductor device 1000 described herein. The semiconductor device 1000 may include an example of a two-dimensional image sensor (e.g., a 2D CIS). The semiconductor device 1000 may be configured to be deployed in various implementations, such as digital cameras, video recorders, night-vision cameras, automotive sensors and cameras, and/or other types of light-sensing implementations.

As shown in FIG. 10, the semiconductor device 1000 may include a plurality of regions, such as the pixel sensor array 1002, a periphery region 1004, a bonding pad region 1006 (which may also be referred to as an E-pad region), and a scribe line region 1008. The pixel sensor array 1002 may include the pixel sensors 1010 of the semiconductor device 1000. The pixel sensors 1010 may be included in a device region 1012 of the semiconductor device 1000. The pixel sensors 1010 may be formed by one or more of the semiconductor processing tools 102-116 using various semiconductor processing techniques, such as photolithography, etching, deposition, CMP, and/or ion implantation, among other examples.

The periphery region 1004 includes logic circuitry 1014 in the device region 1012 of the semiconductor device 1000. The logic circuitry 1014 may include one or more application-specific integrated circuit (ASIC) devices, one or more system-on-chip (SOC) devices, one or more transistors, and/or one or more other components configured to measure the magnitude of a photocurrent generated by the pixel sensors 1010 to determine light intensity of incident light and/or to generate images and/or video (e.g., digital images, digital video). The semiconductor device 1000 includes an example of a 2D CIS in which the pixel sensor array 1002 and the logic circuitry 1014 are included on the same semiconductor die.

The bonding pad region 1006 may include one or more conductive bonding pads (or e-pads) and/or metallization layers through which electrical connections between the semiconductor device 1000 and outside devices and/or external packaging may be established. The scribe line region 1008 may include a region that separates one semiconductor die or portion of a semiconductor die that includes the semiconductor device 1000 from an adjacent semiconductor die or portion of the semiconductor die that includes other image sensors and/or other integrated circuits.

As further shown in FIG. 10, the semiconductor device 1000 may include various layers and/or structures. As shown in FIG. 10, the semiconductor device 1000 may include a BEOL region 1016 below and/or under the device region 1012. The BEOL region 1016 may include a dielectric region 1018 that includes one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), borosilicate glass (BSG), carbon doped silicon oxide, or another dielectric material. The dielectric region 1018 may include one or more dielectric layers, such as one or more of the dielectric layers 302a-302c, 304a-304c, 306a-306g, 308a-308g, 502-506, 602-606, 702, and/or 802, among other examples.

Various metallization layers 1020 may be formed in and/or in between the layers of the dielectric region 1018. The metallization layers 1020 may include bonding pads, conductive lines, trenches, and/or other types of conductive structures that electrically connect the various regions of the semiconductor device 1000 and/or electrically connect the various regions of the semiconductor device 1000 to one or more external devices and/or external packaging. The metallization layers 1020 may be connected together by interconnects 1022, which may also be referred to as vias. The metallization layers 1020 and the interconnects 1022 may be referred to as a BEOL metallization stack, and may include a conductive material, such as gold, copper, silver, cobalt, tungsten, a metal alloy, or a combination thereof, among other examples.

As further shown in FIG. 10, one or more of the deep trench capacitor structures 260 having a plurality of fin portions 310 may be included in the dielectric region 1018 of the BEOL region 1016 in the semiconductor device 1000. Thus, the one or more of the deep trench capacitor structures 260 may be located below and/or under the pixel sensors 1010 and/or the logic circuitry 1014 in the device region 1012. The plurality of fin portions 310 of a deep trench capacitor structure 260 may extend laterally outward from the central portion 312 of the deep trench capacitor structure 260 in two or more directions (e.g., an x-direction, a y-direction) in the semiconductor device 1000 that are approximately perpendicular with a direction (e.g., a z-direction) in which the central portion 312 extends in the semiconductor device 1000.

The one or more deep trench capacitor structures 260 may be configured to store a photocurrent associated with the plurality of pixel sensors 1010 in the pixel sensor array 1002. In particular, the deep trench capacitor structures 260 having a plurality of fin portions may be included to improve rolling shutter in the semiconductor device 1000. Rolling shutter is achieved through progressive exposure of the pixel sensors 1010 in the pixel sensor array 1002 to incident light. At the beginning of an exposure operation, the logic circuitry 1014 scans the pixel sensors 1010 line by line in the pixel sensor array 1002 for exposure until all of the pixel sensors 1010 are exposed. All actions are completed in a very short time, and the exposure time of different rows of pixel sensors 1010 is different. Therefore, the exposure operation may produce incomplete images and/or distortions when capturing fast-moving objects using such progressive exposure. This may result in deformed images due to the output time difference. The one or more deep trench capacitor structures 260 may enable a global shutter exposure operation to be performed in the semiconductor device 1000. In the global shutter exposure operation, all of the pixel sensors 1010 in the of the pixel sensor array 1002 are exposed simultaneously. At the start of the global shutter exposure operation, each pixel sensor 1010 simultaneously begins to collect charge and generate a photocurrent, and is allowed to do so for the duration of the exposure time of the global shutter exposure operation. Each pixel sensor 1010 transfers a photocurrent to the one or more deep trench capacitor structures 260 for accumulation simultaneously. At the end of the global shutter exposure operation, the one or more deep trench capacitor structures 260 transfers the photocurrents to the logic circuitry 1014.

In some implementations, the semiconductor device 1000 may be mounted and/or fabricated on a carrier substrate 1024 during one or more semiconductor processing operations to form the semiconductor device 1000. The carrier substrate 1024 may be attached to the dielectric region 1018 of the BEOL region 1016 to enable layers and/or structures of the pixel sensors 1010 to be formed. In some implementations, the carrier substrate 1024 may be removed after completion of the semiconductor device 1000 or after a particular portion of the semiconductor device 1000 is completed. In some implementations, the deep trench capacitor structure 260 is formed prior to the semiconductor device 1000 being mounted to the carrier substrate 1024.

As indicated above, FIG. 10 is provided as an example. Other examples may differ from what is described with regard to FIG. 10.

FIG. 11 is a diagram of an example semiconductor device 1100 described herein. The semiconductor device 1100 may include an example of a three-dimensional image sensor (e.g., a 3D CIS). The semiconductor device 1100 may be configured to be deployed in various implementations, such as digital cameras, video recorders, night-vision cameras, automotive sensors and cameras, and/or other types of light-sensing implementations.

As shown in FIG. 11, the semiconductor device 1100 includes a similar combination of structures and/or layers as the semiconductor device 1000. For example, the semiconductor device 1100 may include elements 1102-1122, which are similar to the elements 1002-1022 of the semiconductor device 1000 illustrated and described in connection with FIG. 10.

However, as shown in FIG. 11, the semiconductor device 1100 is a 3D CIS in which a first semiconductor die 1124a (e.g., a sensor die) and a second semiconductor die 1124b (e.g., a logic die) are bonded at a bonding interface 1126 such that the first semiconductor die 1124a and the second semiconductor die 1124b are stacked and/or vertically arranged in the semiconductor device 1100. Unlike the semiconductor device 1000, in which the pixel sensor array 1002 and the logic circuitry 1014 are included on the same semiconductor die and/or in the same device region 1012, the pixel sensor array 1102 and the logic circuitry 1114 are included on different semiconductor dies and in different device regions. For example, the pixel sensors 1110 of the pixel sensor array 1102 may be included in the device region 1112 of the semiconductor die 1124a, and the logic circuitry 1114 may be included in a device region 1128 of the second semiconductor die 1124b.

The one or more deep trench capacitor structures 260 may also be included on the first semiconductor die 1124a. The one or more deep trench capacitor structures 260 may be included in the dielectric region 1118 of the BEOL region 1116 of the first semiconductor die 1124a. The one or more deep trench capacitor structures 260 may be located between the second semiconductor die 1124b and the pixel sensor array 1102 in the first semiconductor die 1124a. The plurality of fin portions 310 of a deep trench capacitor structure 260 may extend laterally outward from the central portion 312 of the deep trench capacitor structure 260 in two or more directions (e.g., an x-direction, a y-direction) in the semiconductor device 1100 that are approximately perpendicular with a direction (e.g., a z-direction) in which the central portion 312 extends in the semiconductor device 1100.

As further shown in FIG. 11, the second semiconductor die 1124b of the semiconductor device 1100 may include various layers and/or structures. The second semiconductor die 1124b of the semiconductor device 1100 may include a BEOL region 1130 above and/or over the device region 1128. A semiconductor processing tool (e.g., the bonding tool 116) may bond the first semiconductor die 1124a and the second semiconductor die 1124b such that the bonding interface 1126 is located between the BEOL region 1116 and the BEOL region 1130. The BEOL region 1130 may include a dielectric region 1132 that includes one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), borosilicate glass (BSG), carbon doped silicon oxide, or another dielectric material.

Various metallization layers 1134 may be formed in and/or in between the layers of the dielectric region 1132. The metallization layers 1134 may include bonding pads, conductive lines, trenches, and/or other types of conductive structures that electrically connect the various regions of the second semiconductor die 1124b of the semiconductor device 1100 and/or electrically connect the various regions of the second semiconductor die 1124b of the semiconductor device 1100 to one or more external devices and/or external packaging. The metallization layers 1134 may be connected together by interconnects 1136, which may also be referred to as vias. The metallization layers 1134 and the interconnects 1136 may be referred to as a BEOL metallization stack, and may include a conductive material, such as gold, copper, silver, cobalt, tungsten, a metal alloy, or a combination thereof, among other examples.

As indicated above, FIG. 11 is provided as an example. Other examples may differ from what is described with regard to FIG. 11.

FIG. 12 is a diagram of an example semiconductor device 1200 described herein. The semiconductor device 1200 may include an example of a three-dimensional image sensor (e.g., a 3D CIS). The semiconductor device 1200 may be configured to be deployed in various implementations, such as digital cameras, video recorders, night-vision cameras, automotive sensors and cameras, and/or other types of light-sensing implementations.

As shown in FIG. 12, the semiconductor device 1200 includes a similar combination of structures and/or layers as the semiconductor device 1100. For example, the semiconductor device 1200 may include elements 1202-1236, which are similar to the elements 1102-1136 of the semiconductor device 1100 illustrated and described in connection with FIG. 11.

However, as shown in FIG. 12, the semiconductor device 1200 includes one or more deep trench capacitor structures 260 on the second semiconductor die 1224b as opposed to the first semiconductor die 1224a. Including the one or more deep trench capacitor structures 260 on the second semiconductor die 1224b as opposed to the first semiconductor die 1224a enables a greater amount of the area in the first semiconductor die 1224a to be used for control circuitry, such as transfer gate transistors, reset gate transistors, source follower transistors, and/or other circuitry associated with the pixel sensors 1210 of the semiconductor device 1200, which may increase the performance of the semiconductor device 1200.

The one or more deep trench capacitor structures 260 may be included in the dielectric region 1232 of the BEOL region 1230 of the second semiconductor die 1224b. The one or more deep trench capacitor structures 260 may be electrically connected with one or more metallization layers 1234 and/or interconnects 1236 in the BEOL region 1230. The plurality of fin portions 310 of a deep trench capacitor structure 260 may extend laterally outward from the central portion 312 of the deep trench capacitor structure 260 in two or more directions (e.g., an x-direction, a y-direction) in the semiconductor device 1200 that are approximately perpendicular with a direction (e.g., a z-direction) in which the central portion 312 extends in the semiconductor device 1200.

As indicated above, FIG. 12 is provided as an example. Other examples may differ from what is described with regard to FIG. 12.

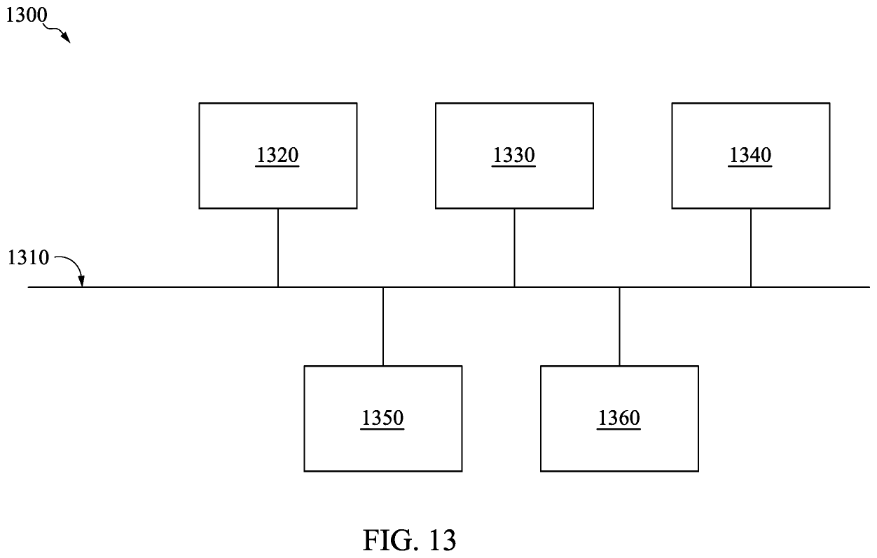

FIG. 13 is a diagram of example components of a device 1300 described herein. In some implementations, one or more of the semiconductor processing tools 102-116 and/or the wafer/die transport tool 118 may include one or more devices 1300 and/or one or more components of the device 1300. As shown in FIG. 13, the device 1300 may include a bus 1310, a processor 1320, a memory 1330, an input component 1340, an output component 1350, and/or a communication component 1360.

The bus 1310 may include one or more components that enable wired and/or wireless communication among the components of the device 1300. The bus 1310 may couple together two or more components of FIG. 13, such as via operative coupling, communicative coupling, electronic coupling, and/or electric coupling. For example, the bus 1310 may include an electrical connection (e.g., a wire, a trace, and/or a lead) and/or a wireless bus. The processor 1320 may include a central processing unit, a graphics processing unit, a microprocessor, a controller, a microcontroller, a digital signal processor, a field-programmable gate array, an application-specific integrated circuit, and/or another type of processing component. The processor 1320 may be implemented in hardware, firmware, or a combination of hardware and software. In some implementations, the processor 1320 may include one or more processors capable of being programmed to perform one or more operations or processes described elsewhere herein.

The memory 1330 may include volatile and/or nonvolatile memory. For example, the memory 1330 may include random access memory (RAM), read only memory (ROM), a hard disk drive, and/or another type of memory (e.g., a flash memory, a magnetic memory, and/or an optical memory). The memory 1330 may include internal memory (e.g., RAM, ROM, or a hard disk drive) and/or removable memory (e.g., removable via a universal serial bus connection). The memory 1330 may be a non-transitory computer-readable medium. The memory 1330 may store information, one or more instructions, and/or software (e.g., one or more software applications) related to the operation of the device 1300. In some implementations, the memory 1330 may include one or more memories that are coupled (e.g., communicatively coupled) to one or more processors (e.g., processor 1320), such as via the bus 1310. Communicative coupling between a processor 1320 and a memory 1330 may enable the processor 1320 to read and/or process information stored in the memory 1330 and/or to store information in the memory 1330.

The input component 1340 may enable the device 1300 to receive input, such as user input and/or sensed input. For example, the input component 1340 may include a touch screen, a keyboard, a keypad, a mouse, a button, a microphone, a switch, a sensor, a global positioning system sensor, an accelerometer, a gyroscope, and/or an actuator. The output component 1350 may enable the device 1300 to provide output, such as via a display, a speaker, and/or a light-emitting diode. The communication component 1360 may enable the device 1300 to communicate with other devices via a wired connection and/or a wireless connection. For example, the communication component 1360 may include a receiver, a transmitter, a transceiver, a modem, a network interface card, and/or an antenna.

The device 1300 may perform one or more operations or processes described herein. For example, a non-transitory computer-readable medium (e.g., memory 1330) may store a set of instructions (e.g., one or more instructions or code) for execution by the processor 1320. The processor 1320 may execute the set of instructions to perform one or more operations or processes described herein. In some implementations, execution of the set of instructions, by one or more processors 1320, causes the one or more processors 1320 and/or the device 1300 to perform one or more operations or processes described herein. In some implementations, hardwired circuitry may be used instead of or in combination with the instructions to perform one or more operations or processes described herein. Additionally, or alternatively, the processor 1320 may be configured to perform one or more operations or processes described herein. Thus, implementations described herein are not limited to any specific combination of hardware circuitry and software.

The number and arrangement of components shown in FIG. 13 are provided as an example. The device 1300 may include additional components, fewer components, different components, or differently arranged components than those shown in FIG. 13. Additionally, or alternatively, a set of components (e.g., one or more components) of the device 1300 may perform one or more functions described as being performed by another set of components of the device 1300.

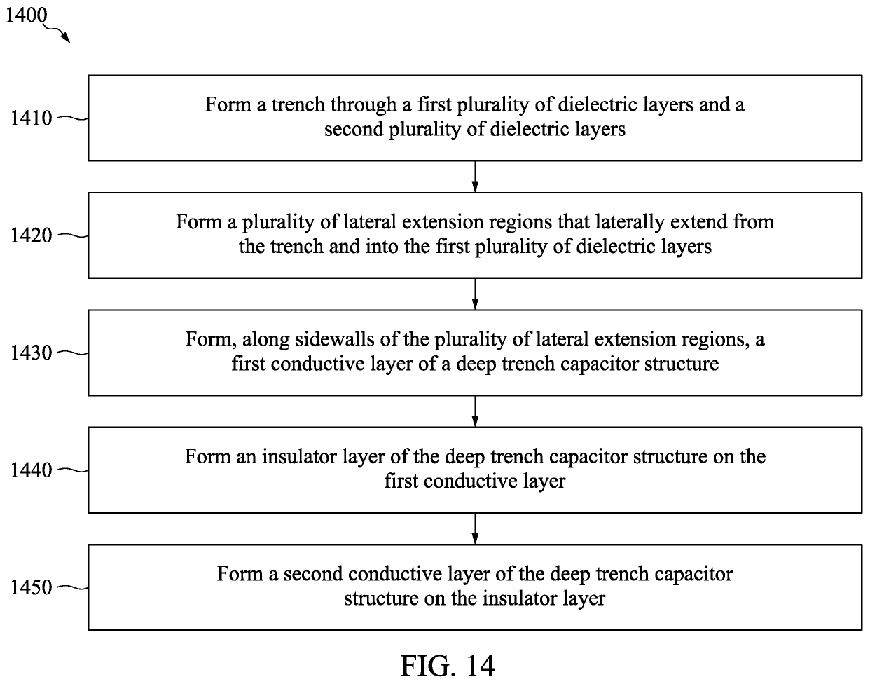

FIG. 14 is a flowchart of an example process 1400 associated with forming a deep trench capacitor structure. In some implementations, one or more process blocks of FIG. 14 are performed by one or more semiconductor processing tools (e.g., one or more of the semiconductor processing tools 102-116). Additionally, or alternatively, one or more process blocks of FIG. 14 may be performed by one or more components of device 1300, such as processor 1320, memory 1330, input component 1340, output component 1350, and/or communication component 1360.

As shown in FIG. 14, process 1400 may include forming a trench through a first plurality of dielectric layers and a second plurality of dielectric layers (block 1410). For example, one or more of the semiconductor processing tools 102-116 may form a trench (e.g., a trench 402, 508, and/or 608) through a first plurality of dielectric layers (e.g., dielectric layers 306a-306g, 502, and/or 602) and a second plurality of dielectric layers (e.g., dielectric layers 216-226, 308a-308g, 504, and/or 604), as described herein. In some implementations, the first plurality of dielectric layers and the second plurality of dielectric layers are arranged in an alternating configuration in a first direction (e.g., a z-direction) in a semiconductor device (e.g., a semiconductor device 200, 1000, 1100, and/or 1200).

As further shown in FIG. 14, process 1400 may include forming a plurality of lateral extension regions that laterally extend from the trench and into the first plurality of dielectric layers (block 1420). For example, one or more of the semiconductor processing tools 102-116 may form a plurality of lateral extension regions (e.g., lateral extension regions 404, 510, and/or 610) that laterally extend from the trench and into the first plurality of dielectric layers, as described herein.

As further shown in FIG. 14, process 1400 may include forming, along sidewalls of the plurality of lateral extension regions, a first conductive layer of a deep trench capacitor structure (block 1430). For example, one or more of the semiconductor processing tools 102-116 may form, along sidewalls of the plurality of lateral extension regions, a first conductive layer 262 of a deep trench capacitor structure 260, as described herein.

As further shown in FIG. 14, process 1400 may include forming an insulator layer of the deep trench capacitor structure on the first conductive layer (block 1440). For example, one or more of the semiconductor processing tools 102-116 may form an insulator layer 264 of the deep trench capacitor structure 260 on the first conductive layer 262, as described herein.

As further shown in FIG. 14, process 1400 may include forming a second conductive layer of the deep trench capacitor structure on the insulator layer (block 1450). For example, one or more of the semiconductor processing tools 102-116 may form a second conductive layer 266 of the deep trench capacitor structure 260 on the insulator layer 264, as described herein.

Process 1400 may include additional implementations, such as any single implementation or any combination of implementations described below and/or in connection with one or more other processes described elsewhere herein.

In a first implementation, forming the trench includes performing a first etch operation to form the trench, and forming the plurality of lateral extension regions includes performing, after the first etch operation, a second etch operation to etch the first plurality of dielectric layers and the second plurality of dielectric layers through the trench to form the plurality of lateral extension regions.

In a second implementation, alone or in combination with the first implementation, forming the plurality of lateral extension regions includes performing, using an etchant, an etch operation to etch the first plurality of dielectric layers and the second plurality of dielectric layers through the trench to form the plurality of lateral extension regions, where the etchant etches the first plurality of dielectric layers at a first etch rate and/or etch back in the etch operation, where the etchant etches the second plurality of dielectric layers at a second etch rate and/or etch back in the etch operation, and where the first etch rate and/or etch back is greater relative to the second etch rate and/or etch back.

In a third implementation, alone or in combination with one or more of the first and second implementations, the first plurality of dielectric layers comprise a plurality of undoped silicate glass (USG) layers, where the second plurality of dielectric layers comprise a plurality of borophosphosilicate glass (BPSG) layers, and where forming the plurality of lateral extension regions comprises performing a buffer oxide etch (BOE) etch operation to etch the plurality of USG layers and the plurality of BPSG layers through the trench to form the plurality of lateral extension regions.

In a fourth implementation, alone or in combination with one or more of the first through third implementations, performing the BOE etch operation includes performing the BOE etch operation using an etchant that includes ammonium fluoride and hydrofluoric acid, where a ratio of the ammonium fluoride to the hydrofluoric acid in the etchant results in a greater etch rate for the plurality of USG layers relative to an etch rate for the plurality of BPSG layers.

In a fifth implementation, alone or in combination with one or more of the first through fourth implementations, the first plurality of dielectric layers include a plurality of phosphosilicate silicon glass (PSG) layers, the second plurality of dielectric layers include a plurality of borosilicate glass (BSG) layers, and forming the plurality of lateral extension regions includes performing a buffer oxide etch (BOE) etch operation to etch the plurality of PSG layers and the plurality of BSG layers through the trench to form the plurality of lateral extension regions.

In a sixth implementation, alone or in combination with one or more of the first through fifth implementations, performing the BOE etch operation includes performing the BOE etch operation using an etchant that includes ammonium fluoride and hydrofluoric acid, wherein a ratio of the ammonium fluoride to the hydrofluoric acid in the etchant results in a greater etch rate for the plurality of PSG layers relative to an etch rate for the plurality of BSG layers.

Although FIG. 14 shows example blocks of process 1400, in some implementations, process 1400 includes additional blocks, fewer blocks, different blocks, or differently arranged blocks than those depicted in FIG. 14. Additionally, or alternatively, two or more of the blocks of process 1400 may be performed in parallel.

In this way, a deep trench capacitor structure may include a MIM structure having an insulator layer between opposing conductive electrode layers. The deep trench capacitor structure may extend through a plurality of dielectric layers in the BEOL region. The conductive electrode layers and the insulator layer may extend laterally into one or more of the dielectric layers. The lateral extensions of the conductive electrode layers and the insulator layer into the one or more dielectric layers may be referred to as fin portions of the capacitor structure. The fin portions may extend laterally outward from a central portion (e.g., a trench portion) of the deep trench capacitor structure. The fin portions of the deep trench capacitor structure enable the surface area of the conductive electrode layers to be increased, which may increase the capacitance of the deep trench capacitor structure with minimal increase to the overall footprint of the deep trench capacitor structure.

As described in greater detail above, some implementations described herein provide a semiconductor device. The semiconductor device includes a plurality of dielectric layers that are arranged in a first direction and extend in a second direction approximately perpendicular with the first direction. The semiconductor device includes a deep trench capacitor structure that extends through the plurality of dielectric layers. The deep trench capacitor structure includes a central portion that extends in the first direction through the plurality of dielectric layers, and a plurality of fin portions that extend laterally outward from the central portion in the second direction.

As described in greater detail above, some implementations described herein provide a method. The method includes forming a trench through a first plurality of dielectric layers and a second plurality of dielectric layers, where the first plurality of dielectric layers and the second plurality of dielectric layers are arranged in an alternating configuration in a first direction in a semiconductor device. The method includes forming a plurality of lateral extension regions that laterally extend from the trench and into the first plurality of dielectric layers. The method includes forming, along sidewalls of the plurality of lateral extension regions, a first conductive layer of a deep trench capacitor structure. The method includes forming an insulator layer of the deep trench capacitor structure on the first conductive layer. The method includes forming a second conductive layer of the deep trench capacitor structure on the insulator layer.

As described in greater detail above, some implementations described herein provide an image sensor device. The image sensor device includes a pixel sensor array that includes a plurality of pixel sensors. The image sensor device includes a dielectric region below the pixel sensor array. The image sensor device includes a deep trench capacitor structure in the dielectric region, where the deep trench capacitor structure includes a central portion that extends in a first direction in the dielectric region, and a plurality of fin portions that extend laterally outward from the central portion in two or more second directions that are approximately perpendicular with the first direction.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of dielectric layers that are arranged in a first direction and extend in a second direction approximately perpendicular with the first direction; and
a deep trench capacitor structure that extends through the plurality of dielectric layers,
wherein the deep trench capacitor structure comprises:
a central portion that extends in the first direction through the plurality of dielectric layers; and
a plurality of fin portions that extend laterally outward from the central portion in the second direction.

2. The semiconductor device of claim 1, wherein the plurality of dielectric layers and the deep trench capacitor structure are included in a back end of line (BEOL) region of the semiconductor device.

3. The semiconductor device of claim 1, wherein the plurality of fin portions extend laterally outward from the central portion in a third direction that is perpendicular with the first direction and the second direction.

4. The semiconductor device of claim 1, wherein at least a subset of the plurality of fin portions have angled walls such that the subset of the plurality of fin portions taper between the central portion and ends of the subset of the plurality of fin portions.

5. The semiconductor device of claim 1, further comprising:
a bottom metal contact below the plurality of fin portions; and
a top metal contact above the plurality of fin portions,
wherein the deep trench capacitor structure is electrically connected with the bottom metal contact and the top metal contact.

6. The semiconductor device of claim 5, wherein the deep trench capacitor structure further comprises:
a bottom contact region, of the central portion of the deep trench capacitor structure, that is electrically connected with the bottom metal contact.

7. The semiconductor device of claim 5, wherein the deep trench capacitor structure further comprises:
a plurality of bottom contact regions, of the central portion of the deep trench capacitor structure, that are electrically connected with the bottom metal contact.

8. A method, comprising:
forming a trench through a first plurality of dielectric layers and a second plurality of dielectric layers,
wherein the first plurality of dielectric layers and the second plurality of dielectric layers are arranged in an alternating configuration in a first direction in a semiconductor device;
forming a plurality of lateral extension regions that laterally extend from the trench and into the first plurality of dielectric layers;
forming, along sidewalls of the plurality of lateral extension regions, a first conductive layer of a deep trench capacitor structure;
forming an insulator layer of the deep trench capacitor structure on the first conductive layer; and
forming a second conductive layer of the deep trench capacitor structure on the insulator layer.

9. The method of claim 8, wherein forming the trench comprises:
performing a first etch operation to form the trench; and
wherein forming the plurality of lateral extension regions comprises:
performing, after the first etch operation, a second etch operation to etch the first plurality of dielectric layers and the second plurality of dielectric layers through the trench to form the plurality of lateral extension regions.

10. The method of claim 8, wherein forming the plurality of lateral extension regions comprises:
performing, using an etchant, an etch operation to etch the first plurality of dielectric layers and the second plurality of dielectric layers through the trench to form the plurality of lateral extension regions,
wherein the etchant etches the first plurality of dielectric layers at a first etch rate and/or etch back in the etch operation,
wherein the etchant etches the second plurality of dielectric layers at a second etch rate and/or etch back in the etch operation, and
wherein the first etch rate and/or etch back is greater relative to the second etch rate and/or etch back.

11. The method of claim 8, wherein the first plurality of dielectric layers comprise a plurality of undoped silicate glass (USG) layers;
wherein the second plurality of dielectric layers comprise a plurality of borophosphosilicate glass (BPSG) layers; and
wherein forming the plurality of lateral extension regions comprises:
performing a buffer oxide etch (BOE) etch operation to etch the plurality of USG layers and the plurality of BPSG layers through the trench to form the plurality of lateral extension regions.

12. The method of claim 11, wherein performing the BOE etch operation comprises:
performing the BOE etch operation using an etchant that includes ammonium fluoride and hydrofluoric acid,
wherein a ratio of the ammonium fluoride to the hydrofluoric acid in the etchant results in a greater etch rate for the plurality of USG layers relative to an etch rate for the plurality of BPSG layers.

13. The method of claim 8, wherein the first plurality of dielectric layers comprise a plurality of phosphosilicate silicon glass (PSG) layers;
wherein the second plurality of dielectric layers comprise a plurality of borosilicate glass (BSG) layers; and
wherein forming the plurality of lateral extension regions comprises:
performing a buffer oxide etch (BOE) etch operation to etch the plurality of PSG layers and the plurality of BSG layers through the trench to form the plurality of lateral extension regions.

14. The method of claim 13, wherein performing the BOE etch operation comprises:
performing the BOE etch operation using an etchant that includes ammonium fluoride and hydrofluoric acid,
wherein a ratio of the ammonium fluoride to the hydrofluoric acid in the etchant results in a greater etch rate for the plurality of PSG layers relative to an etch rate for the plurality of BSG layers.

15. An image sensor device, comprising:
a pixel sensor array comprising a plurality of pixel sensors;
a dielectric region below the pixel sensor array; and
a deep trench capacitor structure in the dielectric region,
wherein the deep trench capacitor structure comprises:
a central portion that extends in a first direction in the dielectric region; and
a plurality of fin portions that extend laterally outward from the central portion in two or more second directions that are approximately perpendicular with the first direction.

16. The image sensor device of claim 15, further comprising:
logic circuitry in a device region of the image sensor device,
wherein the plurality of pixel sensors are included in the device region, and
wherein the deep trench capacitor structure is located below the device region.

17. The image sensor device of claim 15, further comprising:
a first semiconductor die comprising:
the pixel sensor array;
the dielectric region; and
the deep trench capacitor structure; and
a second semiconductor die, bonded with the first semiconductor die at a bonding interface, comprising:
logic circuitry of the image sensor device.

18. The image sensor device of claim 17, wherein the deep trench capacitor structure is located between the second semiconductor die and the pixel sensor array in the first semiconductor die.

19. The image sensor device of claim 15, wherein the dielectric region is included in a back end of line (BEOL) region of the image sensor device.

20. The image sensor device of claim 15, wherein the deep trench capacitor structure is configured to store a photocurrent associated with the plurality of pixel sensors.
